(19) United States
(12) Patent Application Publication
(10) Pub. No.: US 2024/0162322 A1
(43) Pub. Date: May 16, 2024

(54) SEMICONDUCTOR DEVICE AND METHOD OF FABRICATING THE SAME

(71) Applicant: Samsung Electronics Co., Ltd., Suwon-si (KR)

(72) Inventors: Jongmin Shin, Suwon-si (KR); Donghoon Hwang, Suwon-si (KR)

(21) Appl. No.: 18/206,139

(22) Filed: Jun. 6, 2023

(30) Foreign Application Priority Data
Nov. 14, 2022 (KR) 10-2022-0151692

(51) Int. Cl. H01L 29/423; H01L 27/092; H01L 29/06; H01L 29/417; H01L 29/775; H01L 29/786

(52) U.S. Cl. CPC H01L 29/42392; H01L 27/092; H01L 29/0673; H01L 29/41733; H01L 29/775; H01L 29/78696

(57) ABSTRACT

A semiconductor device may include an active region on a substrate, channel patterns on the active region, and gate electrodes on the channel patterns, respectively, and extending in a first direction. The channel patterns may include a first subset of the channel patterns, each of which has a first width, and a second subset of the channel patterns, each of which has a second width. The first and second subsets may be adjacent to each other in a second direction. The channel patterns may further include a buffer channel pattern between the first subset and the second subset. The buffer channel pattern may include a connection side surface extending in the first direction, and the connection side surface may be configured such that a width of the buffer channel pattern changes from the first width to the second width when moving from the first subset to the second subset.

### CROSS-REFERENCE TO RELATED APPLICATIONS

This U.S. non-provisional patent application claims priority under 35 U.S.C. § 119 to Korean Patent Application No. 10-2022-0151692, filed on Nov. 14, 2022, in the Korean Intellectual Property Office, the entire contents of which are hereby incorporated by reference.

### BACKGROUND

The present disclosure relates to a semiconductor device and a method of fabricating the same, and in particular, to a semiconductor device including a field effect transistor and a method of fabricating the same.

A semiconductor device may include an integrated circuit composed of metal-oxide-semiconductor field-effect transistors (MOS-FETs). To meet an increasing demand for a semiconductor device with a small pattern size and a reduced design rule, the MOS-FETs are being aggressively scaled down. The scale-down of the MOS-FETs may lead to deterioration in operational properties of the semiconductor device. A variety of studies are being conducted to overcome technical limitations associated with the scale-down of the semiconductor device and to realize semiconductor devices with high performance.

### SUMMARY

Example embodiments of the inventive concept provide a semiconductor device with improved reliability and electric characteristics.

Example embodiments of the inventive concept provide a method of fabricating a semiconductor device with improved reliability and electric characteristics.

According to some embodiments of the inventive concept, a semiconductor device may include an active region on a substrate, source/drain patterns on the active region, channel patterns on the active region and electrically connected to respective pairs of the source/drain patterns, each of the channel patterns including a plurality of semiconductor patterns that are vertically stacked and spaced apart from each other, gate electrodes that are on the channel patterns, respectively, and extend in a first direction parallel to each other, and active contacts electrically connected to the source/drain patterns, respectively. The channel patterns may include a first subset of the channel patterns, each of which has a first width in the first direction, and a second subset of the channel patterns, each of which has a second width in the first direction. The first subset and the second subset of the channel patterns may be adjacent to each other in a second direction that intersects the first direction. The channel patterns may further include a buffer channel pattern between the first subset and the second subset of the channel patterns. The buffer channel pattern may include a connection side surface that extends in the first direction, and the connection side surface may be configured such that a width of the buffer channel pattern changes from the first width to the second width when moving from the first subset to the second subset of the channel patterns.

According to some embodiments of the inventive concept, a semiconductor device may include an active region on a substrate, a source/drain pattern on the active region, a channel pattern on the active region and electrically connected to the source/drain pattern, the channel pattern including a plurality of semiconductor patterns that are vertically stacked and spaced apart from each other, a gate electrode that is on the channel pattern and extends in a first direction, the gate electrode having a first horizontal width in a second direction that intersects the first direction, and an active contact electrically connected to the source/drain pattern. The channel pattern may include a first region that has a first width in the first direction, a second region that has a second width in the first direction, and a third region between the first region and the second region. The third region may have a varying channel width. The third region may have a third width in the first direction, and the third region may have a second horizontal width in the second direction. The second horizontal width may be smaller than the first horizontal width.

According to some embodiments of the inventive concept, a semiconductor device may include a substrate that includes an active region, a device isolation layer that defines the active region, source/drain patterns on the active region, channel patterns on the active region and electrically connected to respective pairs of the source/drain patterns, each of the channel patterns including a plurality of semiconductor patterns that are vertically stacked and spaced apart from each other, gate electrodes that are on the channel patterns, respectively, and extend in a first direction parallel to each other, gate insulating layers, each of the gate insulating layers between a respective one of the gate electrodes and a respective one of the channel patterns, gate spacers, each of the gate spacers on a side surface of a respective one of the gate electrodes, gate capping patterns, each of the gate capping patterns on a top surface of a respective one of the gate electrodes, an interlayer insulating layer on the gate capping pattern, active contacts that extend into the interlayer insulating layer and are electrically connected to the source/drain patterns, respectively, metal-semiconductor compound layers, each of the metal semiconductor compound layers between a respective one of the active contacts and a respective one of the source/drain patterns, gate contacts that extend into the interlayer insulating layer and the gate capping pattern and are electrically connected to the gate electrodes, respectively, a first metal layer on the interlayer insulating layer, and a second metal layer on the first metal layer. The first metal layer may include first interconnection lines that are electrically connected to at least one of the active contacts and the gate contacts, and the second metal layer may include second interconnection lines that are electrically connected to the first metal layer. The channel patterns may include a first subset of the channel patterns, each of which has a first width in the first direction, and a second subset of the channel patterns, each of which has a second width in the first direction. The channel patterns may further include a buffer channel pattern between the first subset and the second subset of the channel patterns. The buffer channel pattern may be configured such that a width of the buffer channel pattern changes from the first width to the second width when moving from the first subset to the second subset of the channel patterns.

### BRIEF DESCRIPTION OF THE DRAWINGS

FIG. 1 is a plan view illustrating a semiconductor device according to some embodiments of the inventive concept.

FIG. 2 is an enlarged view illustrating a portion ‘IVY of FIG. 1.

FIGS. 3A to 3E are sectional views taken along lines A-A’, B-B′, C-C′, D-D′, and E-E′ of FIG. 2, respectively.

FIG. 4 is a sectional view taken along a line N-N′ of FIG. 3B.

FIGS. 5A, 6A, and 7A are enlarged plan views illustrating the portion ‘IVY of FIG. 1.

FIGS. 5B, 6B, and 7B are sectional views taken along the line N-N’ of FIG. 3B.

FIGS. 8, 9A, 9B, 10, 11, 12A, 12B, 13A to 13C, 14, 15A to 15C, 16, 17A to 17C, 18A, 18B, 19, and 20A to 20E are diagrams illustrating a method of fabricating a semiconductor device, according to some embodiments of the inventive concept.

### DETAILED DESCRIPTION

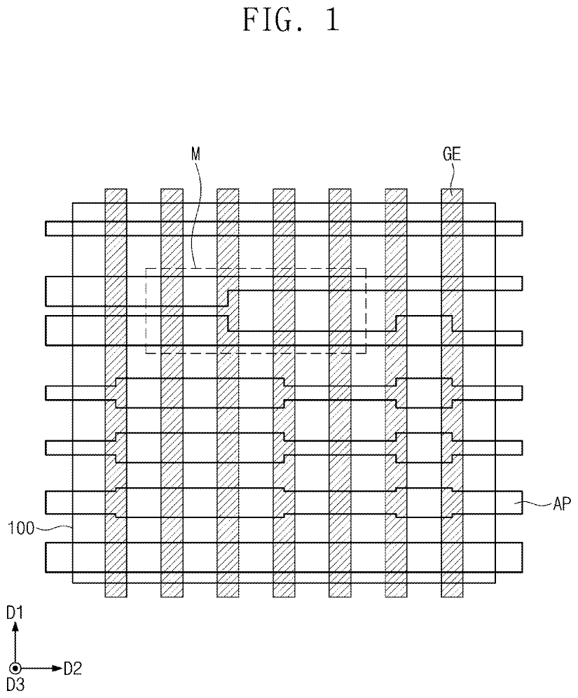

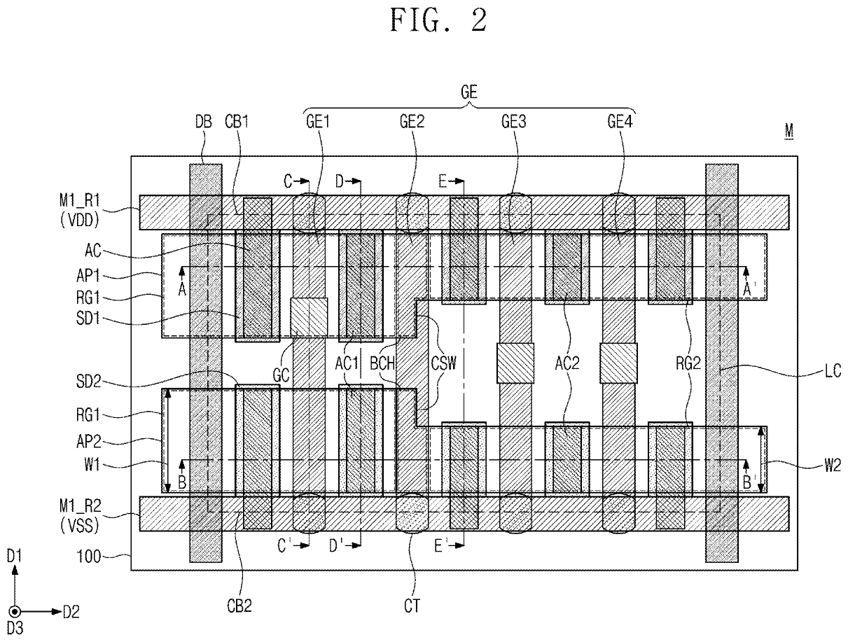

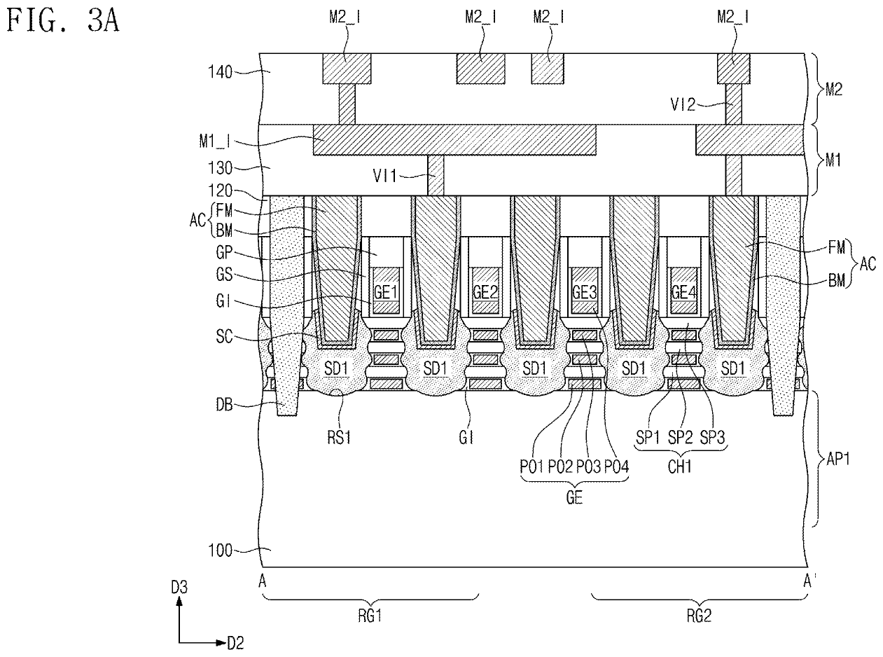

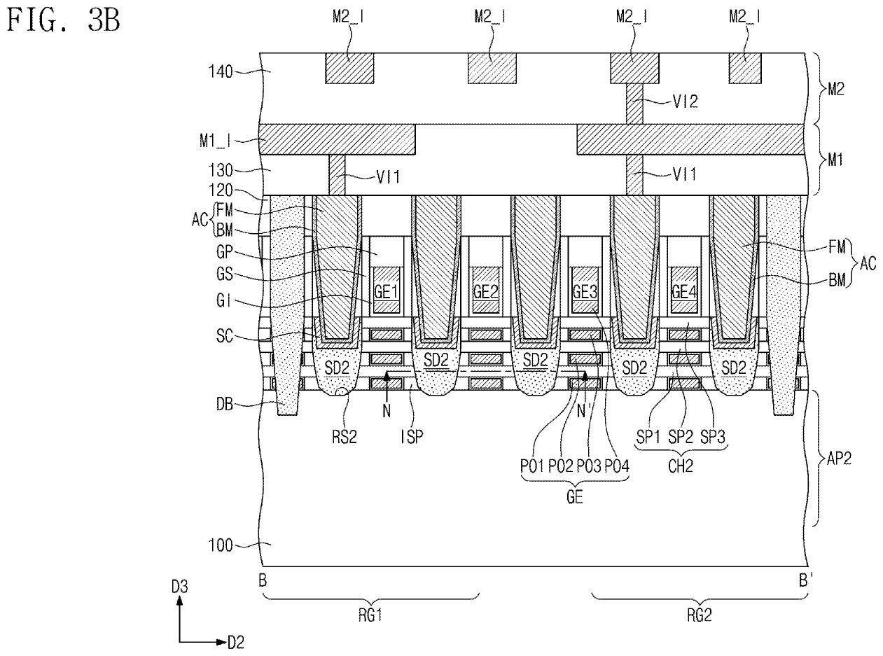

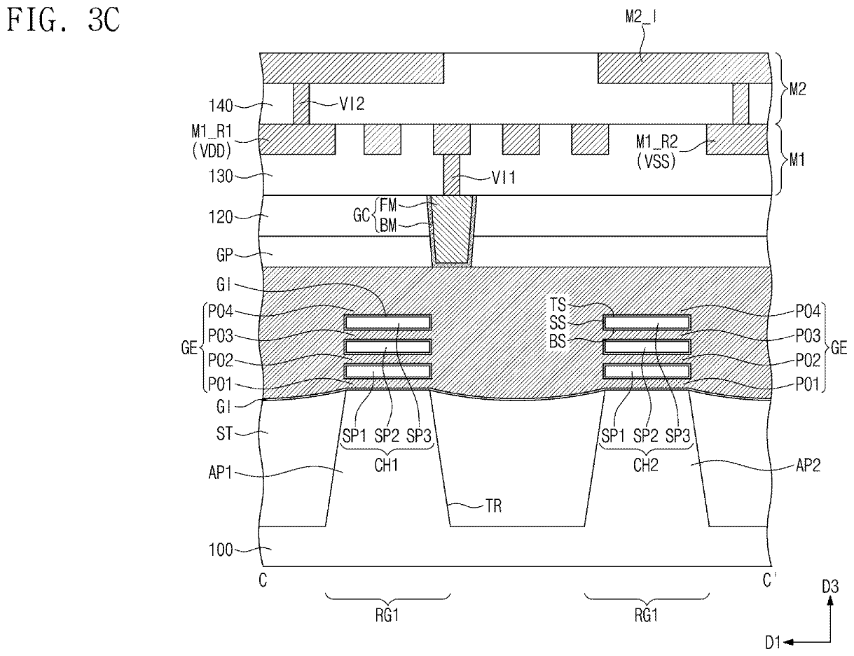

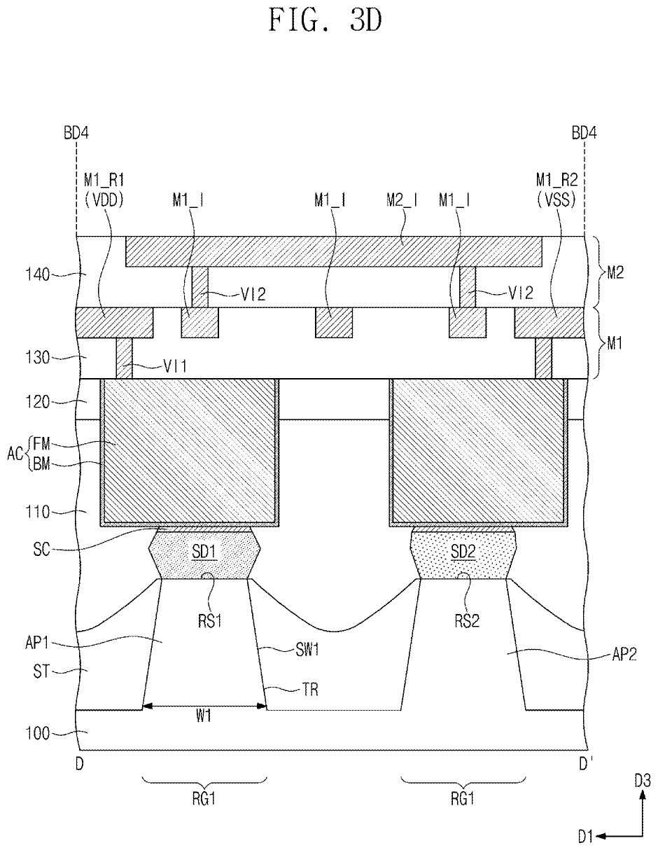

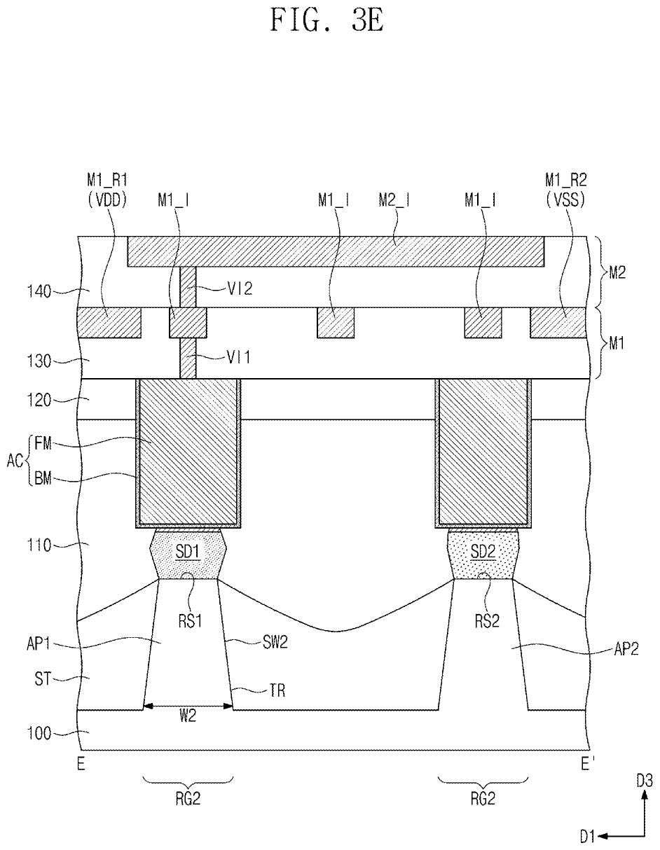

FIG. 1 is a plan view illustrating a semiconductor device according to some embodiments of the inventive concept. FIG. 2 is an enlarged view illustrating a portion ‘M’ of FIG. 1. FIGS. 3A to 3E are sectional views taken along lines A-A′, B-B′, C-C′, D-D′, and E-E′ of FIG. 2, respectively.

Referring to FIG. 1, active regions AP may be provided on a substrate 100. The active regions AP may extend in a second direction D2 parallel to each other. The active region AP may have a width in a first direction D1. As a position in the second direction D2 is changed, the width of the active region AP in the first direction D1 may be variously changed. For example, the first and second directions D1 and D2 may extend parallel to a top surface of the substrate 100 and may be perpendicular to each other. For example, the second direction may intersect the first direction.

Gate electrodes GE may be provided on the active regions AP. The gate electrodes GE may extend in the first direction D1 parallel to each other. The gate electrode GE may have a width in the second direction D2. In some embodiments, the width of the gate electrode GE may be constant.

Referring to FIG. 2 and FIGS. 3A to 3E, a logic cell LC may be provided on a substrate 100. Logic transistors constituting a logic circuit may be disposed on the logic cell LC. The substrate 100 may be a semiconductor substrate that is formed of or includes silicon, germanium, silicon germanium, a compound semiconductor material, or the like. In some embodiments, the substrate 100 may be a silicon wafer.

The logic cell LC may include a first active region AP1 and a second active region AP2. The first and second active regions AP1 and AP2 may be defined by a trench TR, which is formed in an upper portion of the substrate 100. In other words, the trench TR may be located between the first and second active regions AP1 and AP2. The first and second active regions AP1 and AP2 may be spaced apart from each other in a first direction D1 with the trench TR interposed therebetween.

Each of the first and second active regions AP1 and AP2 may be a vertically-protruding upper portion of the substrate 100. The first and second active regions AP1 and AP2 may extend in a second direction D2 parallel to each other.

A device isolation layer ST may be provided to fill the trench TR. The device isolation layer ST may cover or be on side surfaces of the first and second active regions AP1 and AP2. In some embodiments, the device isolation layer ST may include a silicon oxide layer.

A plurality of first channel patterns CH1 and a plurality of first source/drain patterns SD1 may be provided on the first active region AP1. The first channel patterns CH1 and the first source/drain patterns SD1 may be alternately arranged in the second direction D2. A plurality of second channel patterns CH2 and a plurality of second source/drain patterns SD2 may be provided on the second active region AP2. The second channel patterns CH2 and the second source/drain patterns SD2 may be alternately arranged in the second direction D2.

Each of the first and second channel patterns CH1 and CH2 may include a first semiconductor pattern SP1, a second semiconductor pattern SP2, and a third semiconductor pattern SP3, which are sequentially stacked. The first to third semiconductor patterns SP1, SP2, and SP3 may be spaced apart from each other in a vertical direction (i.e., a third direction D3). For example, the third direction D3 may extend perpendicular to a top surface of the substrate 100 and may be perpendicular to the first and second directions D1 and D2. Each of the first to third semiconductor patterns SP1, SP2, and SP3 may be formed of or include at least one of silicon (Si), germanium (Ge), or silicon germanium (SiGe). In some embodiments, each of the first to third semiconductor patterns SP1, SP2, and SP3 may be formed of or include silicon (Si).

The first source/drain patterns SD1 may be impurity regions of a first conductivity type (e.g., p-type). The first channel pattern CH1 may be interposed between each pair of the first source/drain patterns SD1. In other words, each pair of the first source/drain patterns SD1 may be connected (e.g., electrically connected) to each other by the stacked first to third semiconductor patterns SP1, SP2, and SP3. For example, adjacent ones of the first source/drain patterns SD1 may be considered a pair. Each of the first source/drain patterns SD1 may be provided in a first recess RS1 between the pair of first channel patterns CH1.

The second source/drain patterns SD2 may be impurity regions of a second conductivity type (e.g., n-type). The second channel pattern CH2 may be interposed between a pair of the second source/drain patterns SD2. In other words, each pair of the second source/drain patterns SD2 may be connected (e.g., electrically connected) to each other by the stacked first to third semiconductor patterns SP1, SP2, and SP3. For example, adjacent ones of the second source/drain patterns SD2 may be considered a pair. Each of the second source/drain patterns SD2 may be provided in a second recess RS2 between the pair of second channel patterns CH2.

The first and second source/drain patterns SD1 and SD2 may be epitaxial patterns, which are formed by a selective epitaxial growth process. In some embodiments, a top surface of each of the first source/drain patterns SD1 may be higher than a top surface of the third semiconductor pattern SP3. A top surface of each of the second source/drain patterns SD2 may be located at substantially the same level as the top surface of the third semiconductor pattern SP3. In some other embodiments, the top surface of each of the second source/drain patterns SD2 may be higher than the top surface of the third semiconductor pattern SP3.

The first source/drain patterns SD1 may include a semiconductor material (e.g., SiGe) whose lattice constant is greater than that of the substrate 100. In this case, the pair of the first source/drain patterns SD1 may exert a compressive stress on the first channel patterns CH1 therebetween. The second source/drain patterns SD2 may be formed of or include the same semiconductor element (e.g., Si) as the substrate 100.

Gate electrodes GE may be provided to cross the first and second active regions AP1 and AP2 and to extend in the first direction D1. The gate electrodes GE may be arranged at a first pitch in the second direction D2. Each of the gate electrodes GE may be vertically overlapped with the first and second channel patterns CH1 and CH2. As used herein, “an element A vertically overlapped with an element B” (or similar language) means that there is at least one line that extends in a vertical direction (e.g., the third direction D3) and intersects both the elements A and B. The gate electrodes GE may include first to fourth gate electrodes GE1-GE4, which are sequentially arranged in the second direction D2.

The gate electrode GE may include a first portion PO1 interposed between the substrate 100 and the first semiconductor pattern SP1, a second portion PO2 interposed between the first semiconductor pattern SP1 and the second semiconductor pattern SP2, a third portion PO3 interposed between the second semiconductor pattern SP2 and the third semiconductor pattern SP3, and a fourth portion PO4 on the third semiconductor pattern SP3.

Referring to FIG. 3A, the first to third portions PO1, PO2, and PO3 of the gate electrode GE on the first active region AP1 may have different widths from each other. For example, the largest width of the first portion PO1 in the second direction D2 may be larger than the largest width of the second portion PO2 in the second direction D2. The largest width of the first portion PO1 in the second direction D2 may be larger than the largest width of the third portion PO3 in the second direction D2. The largest width of the second portion PO2 in the second direction D2 may be larger or smaller than the largest width of the third portion PO3 in the second direction D2.

Referring to FIG. 3C, the gate electrode GE may be provided on a top surface TS, a bottom surface BS, and opposite side surfaces SS of each of the first to third semiconductor patterns SP1, SP2, and SP3. That is, the transistor in the logic cell LC according to some embodiments may be a three-dimensional field effect transistor (e.g., a multi-bridge channel field effect transistor (MBCFET) or a gate-all-around FET (GAAFET)) in which the gate electrode GE is provided to three-dimensionally surround the channel pattern (e.g., the first and second channel patterns CH1 and CH2).

Referring to FIG. 2 and FIGS. 3A to 3E, a pair of gate spacers GS may be respectively disposed on opposite side surfaces of the fourth portion PO4 of the gate electrode GE. The gate spacers GS may extend along the gate electrode GE in the first direction D1. Top surfaces of the gate spacers GS may be higher than a top surface of the gate electrode GE. The top surfaces of the gate spacers GS may be coplanar with a top surface of a first interlayer insulating layer 110, which will be described below. The gate spacers GS may be formed of or include at least one of SiCN, SiCON, or SiN. In some embodiments, the gate spacers GS may be a multi-layered structure, which includes at least two different materials selected from SiCN, SiCON, and SiN.

A gate capping pattern GP may be provided on the gate electrode GE. The gate capping pattern GP may extend along the gate electrode GE in the first direction D1. The gate capping pattern GP may be formed of or include a material having an etch selectivity with respect to first and second interlayer insulating layers 110 and 120, which will be described below. For example, the gate capping patterns GP may be formed of or include at least one of SiON, SiCN, SiCON, or SiN.

A gate insulating layer GI may be interposed between the gate electrode GE and the first channel pattern CH1 and between the gate electrode GE and the second channel pattern CH2. The gate insulating layer GI may cover or be on the top surface TS, the bottom surface BS, and the opposite side surfaces SS of each of the first to third semiconductor patterns SP1, SP2, and SP3. The gate insulating layer GI may cover or be on a top surface of the device isolation layer ST, which is located below the gate electrode GE (e.g., see FIG. 3C).

Although not shown, the gate electrode GE may include a first metal pattern and a second metal pattern on the first metal pattern. The first metal pattern may be provided on the gate insulating layer GI and may be adjacent to the first to third semiconductor patterns SP1, SP2, and SP3. The first metal pattern may include a work-function metal, which can be used to adjust a threshold voltage of the transistor. By adjusting a thickness and composition of the first metal pattern, it may be possible to realize a transistor having a desired threshold voltage. For example, the first to third portions PO1, PO2, and PO3 of the gate electrode GE may be composed of the first metal pattern or the work-function metal.

The first metal pattern may include a metal nitride layer. For example, the first metal pattern may include nitrogen (N) and at least one metal selected from titanium (Ti), tantalum (Ta), aluminum (Al), tungsten (W), and molybdenum (Mo). In addition, the first metal pattern may further include carbon (C). The first metal pattern may include a plurality of work function metal layers which are stacked.

The second metal pattern may be formed of or include a metallic material whose resistance is lower than the first metal pattern. For example, the second metal pattern may be formed of or include at least one metallic material, which is selected from the group consisting of tungsten (W), aluminum (Al), titanium (Ti), and tantalum (Ta). The fourth portion PO4 of the gate electrode GE may include the first metal pattern and the second metal pattern on the first metal pattern.

In some embodiments, the gate insulating layer GI may include a silicon oxide layer, a silicon oxynitride layer, and/or a high-k dielectric layer. For example, the gate insulating layer GI may have a structure, in which a silicon oxide layer and a high-k dielectric layer are stacked. The high-k dielectric layer may be formed of or include at least one of high-k dielectric materials whose dielectric constants are higher than that of silicon oxide. For example, the high-k dielectric material may include at least one of hafnium oxide, hafnium silicon oxide, hafnium zirconium oxide, hafnium tantalum oxide, lanthanum oxide, zirconium oxide, zirconium silicon oxide, tantalum oxide, titanium oxide, barium strontium titanium oxide, barium titanium oxide, strontium titanium oxide, lithium oxide, aluminum oxide, lead scandium tantalum oxide, or lead zinc niobate.

In some other embodiments, the semiconductor device may include a negative capacitance (NC) FET (i.e., an NC-FET) using a negative capacitor. For example, the gate insulating layer GI may include a ferroelectric layer exhibiting a ferroelectric property and a paraelectric layer exhibiting a paraelectric property.

The ferroelectric layer may have a negative capacitance, and the paraelectric layer may have a positive capacitance. In the case where two or more capacitors are connected in series and each capacitor has a positive capacitance, a total capacitance may be reduced to a value that is less than a capacitance of each of the capacitors. By contrast, in the case where at least one of serially-connected (i.e., connected in series) capacitors has a negative capacitance, a total capacitance of the serially-connected capacitors may have a positive value and may be greater than an absolute value of each individual capacitance.

In the case where a ferroelectric layer having a negative capacitance and a paraelectric layer having a positive capacitance are connected in series, a total capacitance of the serially-connected ferroelectric and paraelectric layers may be increased. Due to such an increase of the total capacitance, a transistor including the ferroelectric layer may have a subthreshold swing (SS), which is less than 60 mV/decade, at the room temperature.

The ferroelectric layer may have the ferroelectric property. The ferroelectric layer may be formed of or include at least one of, for example, hafnium oxide, hafnium zirconium oxide, barium strontium titanium oxide, barium titanium oxide, and/or lead zirconium titanium oxide. Here, the hafnium zirconium oxide may be hafnium oxide that is doped with zirconium (Zr). Alternatively, the hafnium zirconium oxide may be a compound composed of hafnium (Hf), zirconium (Zr), and/or oxygen (O).

The ferroelectric layer may further include dopants. For example, the dopants may include at least one of aluminum (Al), titanium (Ti), niobium (Nb), lanthanum (La), yttrium (Y), magnesium (Mg), silicon (Si), calcium (Ca), cerium (Ce), dysprosium (Dy), erbium (Er), gadolinium (Gd), germanium (Ge), scandium (Sc), strontium (Sr), or tin (Sn). The kind of the dopants in the ferroelectric layer may vary depending on a ferroelectric material included in the ferroelectric layer.

In the case where the ferroelectric layer includes hafnium oxide, the dopants in the ferroelectric layer may include at least one of, for example, gadolinium (Gd), silicon (Si), zirconium (Zr), aluminum (Al), and/or yttrium (Y).

In the case where the dopants are aluminum (Al), a content of aluminum in the ferroelectric layer may range from 3 to 8 at % (atomic percentage). Here, the content of the dopants (e.g., aluminum atoms) may be a ratio of the number of aluminum atoms to the number of hafnium and aluminum atoms.

In the case where the dopants are silicon (Si), a content of silicon in the ferroelectric layer may range from 2 at % to 10 at %. In the case where the dopants are yttrium (Y), a content of yttrium in the ferroelectric layer may range from 2 at % to 10 at %. In the case where the dopants are gadolinium (Gd), a content of gadolinium in the ferroelectric layer may range from 1 at % to 7 at %. In the case where the dopants are zirconium (Zr), a content of zirconium in the ferroelectric layer may range from 50 at % to 80 at %.

The paraelectric layer may have the paraelectric property. The paraelectric layer may be formed of or include at least one of, for example, silicon oxide and/or high-k metal oxides. The metal oxides, which can be used as the paraelectric layer, may include at least one of, for example, hafnium oxide, zirconium oxide, and/or aluminum oxide, but the inventive concept is not limited to these examples.

The ferroelectric layer and the paraelectric layer may be formed of or include the same material. The ferroelectric layer may have the ferroelectric property, but the paraelectric layer may not have the ferroelectric property. For example, in the case where the ferroelectric and paraelectric layers contain hafnium oxide, a crystal structure of the hafnium oxide in the ferroelectric layer may be different from a crystal structure of the hafnium oxide in the paraelectric layer.

The ferroelectric layer may exhibit the ferroelectric property, only when its thickness is in a specific range. In some embodiments, the ferroelectric layer may have a thickness ranging from 0.5 to 10 nm, but the inventive concept is not limited to this example. Since a critical thickness associated with the occurrence of the ferroelectric property varies depending on the kind of the ferroelectric material, the thickness of the ferroelectric layer may be changed depending on the kind of the ferroelectric material.

As an example, the gate insulating layer GI may include a single ferroelectric layer. As another example, the gate insulating layer GI may include a plurality of ferroelectric layers spaced apart from each other. The gate insulating layer GI may have a multi-layered structure, in which a plurality of ferroelectric layers and a plurality of paraelectric layers are alternately stacked.

Referring to FIG. 3B, inner spacers ISP may be provided on an NMOSFET region. The inner spacers ISP may be respectively interposed between the second source/drain pattern SD2 and the first to third portions PO1, PO2, and PO3 of the gate electrode GE. The inner spacers ISP may be in direct contact with the second source/drain pattern SD2. Each of the first to third portions PO1, PO2, and PO3 of the gate electrode GE may be spaced apart from the second source/drain pattern SD2 by the inner spacer ISP.

Referring to FIG. 2 and FIGS. 3A to 3E, a first interlayer insulating layer 110 may be provided on the substrate 100. The first interlayer insulating layer 110 may cover or be on the gate spacers GS and the first and second source/drain patterns SD1 and SD2. The first interlayer insulating layer 110 may have a top surface that is substantially coplanar with the top surface of the gate capping pattern GP and the top surface of the gate spacer GS. A second interlayer insulating layer 120 may be formed on the first interlayer insulating layer 110 to cover or be on the gate capping pattern GP. In some embodiments, at least one of the first and second interlayer insulating layers 110 and 120 may include a silicon oxide layer.

A first cell border CB1 extending in the second direction D2 may be defined in the logic cell LC. A second cell border CB2 may be defined in a region of the logic cell LC opposite to the first cell border CB1. Gate cutting patterns CT may be disposed on the first and second borders CB1 and CB2. When viewed in a plan view, the gate cutting patterns CT may be disposed to be overlapped with the gate electrodes GE, respectively. For example, the gate cutting patterns CT may be overlapped with the gate electrodes GE in the third direction D3, respectively.

The gate cutting pattern CT may be provided to penetrate or extend into the gate electrode GE. The gate cutting pattern CT may extend from the device isolation layer ST to the gate capping pattern GP in the third direction D3. The gate cutting pattern CT may be formed of or include at least one of insulating materials (e.g., silicon nitride, silicon oxide, or combinations thereof). The gate electrode GE of the logic cell LC may be separated from a gate electrode of a neighboring logic cell by the gate cutting pattern CT.

A pair of division structures DB, which are opposite to each other in the second direction D2, may be provided at both sides of the logic cell LC. The division structure DB may extend in the first direction D1 parallel to the gate electrodes GE. A pitch between the division structure DB and the gate electrode GE adjacent thereto may be equal to the first pitch.

The division structure DB may be provided to penetrate or extend into the first and second interlayer insulating layers 110 and 120 and may extend into the first and second active regions AP1 and AP2. The division structure DB may be provided to penetrate or extend into an upper portion of each of the first and second active regions AP1 and AP2. The division structure DB may separate the first and second active regions AP1 and AP2 of the logic cell LC from the active region of a neighboring logic cell.

Active contacts AC may be provided to penetrate or extend into the first and second interlayer insulating layers 110 and 120 and to be electrically connected to the first and second source/drain patterns SD1 and SD2, respectively. A pair of the active contacts AC may be respectively provided at or on both sides of the gate electrode GE. When viewed in a plan view, the active contact AC may be a bar-shaped pattern that extends in the first direction D1.

The active contact AC may be a self-aligned contact. For example, the active contact AC may be formed by a self-alignment process using the gate capping pattern GP and the gate spacer GS. For example, the active contact AC may cover or be on at least a portion of the side surface of the gate spacer GS. Although not shown, the active contact AC may be provided to cover or be on a portion of the top surface of the gate capping pattern GP.

Metal-semiconductor compound layers SC may be respectively interposed between the active contact AC and the first source/drain pattern SD1 and between the active contact AC and the second source/drain pattern SD2. The active contact AC may be electrically connected to the source/drain pattern SD1 or SD2 through the metal-semiconductor compound layer SC. The metal-semiconductor compound layer SC may be formed of or include at least one of metal silicides (e.g., titanium silicide, tantalum silicide, tungsten silicide, nickel silicide, or cobalt silicide).

A gate contact GC may be provided to penetrate or extend into the second interlayer insulating layer 120 and the gate capping pattern GP and to be electrically connected to the gate electrode GE.

Each of the active and gate contacts AC and GC may include a conductive pattern FM and a barrier pattern BM enclosing or at least partially surrounding the conductive pattern FM. For example, the conductive pattern FM may be formed of or include at least one of metallic materials (e.g., aluminum, copper, tungsten, molybdenum, or cobalt). The barrier pattern BM may be provided to cover or be on side and bottom surfaces of the conductive pattern FM. In some embodiments, the barrier pattern BM may include a metal layer and a metal nitride layer. The metal layer may be formed of or include at least one of titanium, tantalum, tungsten, nickel, cobalt, or platinum. The metal nitride layer may be formed of or include at least one of titanium nitride (TiN), tantalum nitride (TaN), tungsten nitride (WN), nickel nitride (NiN), cobalt nitride (CoN), or platinum nitride (PtN).

A first metal layer M1 may be provided in a third interlayer insulating layer 130. The first metal layer M1 may include a first power line M1_R1, a second power line M1_R2, and lower interconnection lines M1_I. The first power line M1_R1, the second power line M1_R2, and the lower interconnection lines M1_I may also be referred to as interconnection lines M1_R1, M1_R2, and M1_I.

Each of the first and second power lines M1_R1 and M1_R2 may extend in the second direction D2 to cross the logic cell LC. In detail, the first power line M1_R1 may be disposed on the first cell border CB1 of the logic cell LC. The first power line M1_R1 may extend along the first cell border CB1 in the second direction D2. The second power line M1_R2 may be disposed on the second cell border CB2 of the logic cell LC. The second power line M1_R2 may extend along the second cell border CB2 in the second direction D2.

The lower interconnection lines M1_I may be disposed between the first and second power lines M1_R1 and M1_R2. The lower interconnection lines M1_I may be line- or bar-shaped patterns extending in the second direction D2. The lower interconnection lines M1_I may be arranged with a second pitch in the first direction D1. In some embodiments, the second pitch may be smaller than the first pitch.

The first metal layer M1 may further include lower vias VI1. The lower vias VI1 may be provided below the interconnection lines M1_R1, M1_R2, and M1_I of the first metal layer M1. The lower vias VI1 may be respectively interposed between the active contacts AC and the interconnection lines M1_R1, M1_R2, and M1_I of the first metal layer M1. In addition, the lower vias VI1 may be respectively interposed between the gate contacts GC and the interconnection lines M1_R1, M1_R2, and M1_I of the first metal layer M1.

The interconnection line M1_R1, M1_R2, or M1_I of the first metal layer M1 and the lower via VI1 thereunder may be formed by separate processes. In other words, each of the interconnection line M1_R1, M1_R2, or M1_I and the lower via VI1 may be formed by a single damascene process. The semiconductor device according to some embodiments may be fabricated using a sub-20 nm process.

A second metal layer M2 may be provided in a fourth interlayer insulating layer 140. The second metal layer M2 may include upper interconnection lines M2_I. Each of the upper interconnection lines M2_I of the second metal layer M2 may be a line- or bar-shaped pattern extending in the first direction D1. In other words, the upper interconnection lines M2_I may extend in the first direction D1 parallel to each other. When viewed in a plan view, the upper interconnection lines M2_I may be parallel to the gate electrodes GE. The upper interconnection lines M2_I may be arranged with a third pitch in the second direction D2. The third pitch may be smaller than the first pitch. The third pitch may be greater than the second pitch.

The second metal layer M2 may further include upper vias VI2. The upper vias VI2 may be provided below the upper interconnection lines M2_I. The upper vias VI2 may be respectively interposed between the upper interconnection lines M2_I and the interconnection lines M1_R1, M1_R2, and M1_I of the first metal layer M1.

The upper interconnection line M2_I of the second metal layer M2 and the upper via VI2 thereunder may be formed by the same process and may form a single object. For example, the upper interconnection line M2_I and the upper via VI2 of the second metal layer M2 may be formed together by a dual damascene process.

The interconnection lines of the first metal layer M1 may be formed of or include a conductive material that is the same as or different from those of the second metal layer M2. For example, the interconnection lines of the first and second metal layers M1 and M2 may be formed of or include at least one of metallic materials (e.g., aluminum, copper, tungsten, molybdenum, or cobalt). Although not shown, a plurality of stacked metal layers (e.g., M3, M4, M5, and so forth) may be further disposed on the fourth interlayer insulating layer 140. Each of the stacked metal layers may include routing lines.

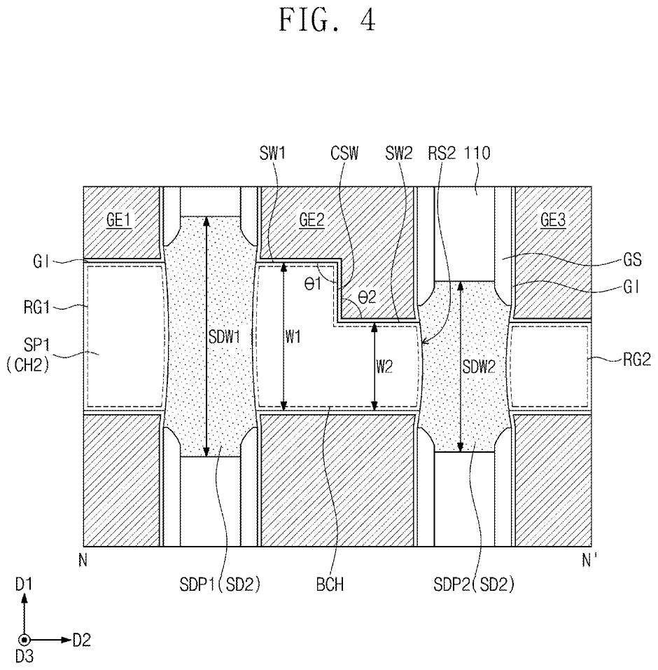

FIG. 4 is a sectional view taken along a line N-N′ of FIG. 3B. Referring to FIG. 4, the channel patterns may include a first region RG1 having a first width W1 and a second region RG2 having a second width W2. For example, the channel patterns may include a first subset of the channel patterns, each of which has a first width W1, and a second subset of the channel patterns, each of which has a second width W2. For example, the first subset of the channel patterns may be included in the first region RG1, and the second subset of the channel patterns may be included in the second region RG2. For example, the first and second widths W1 and W2 may be taken along the first direction D1. The first subset of the channel patterns and the second subset of the channel patterns may be adjacent to each in the second direction D2. The channel patterns may further include a buffer channel pattern BCH positioned between the first region RG1 and the second region RG2. For example, the buffer channel pattern BCH may be between the first subset of the channel patterns and the second subset of the channel patterns. The buffer channel pattern BCH may include a connection side surface CSW that is parallel to the first direction D1. For example, the connection side surface CSW may extend in the first direction D1.

Between the first region RG1 and the second region RG2, the channel pattern may have an abruptly-varying channel width. The buffer channel pattern BCH may be interposed between the first region RG1 and the second region RG2. The buffer channel pattern BCH may be configured such that the channel width is changed from the first width W1 of the first region RG1 to the second width W2 of the second region RG2. For example, the buffer channel pattern BCH may be configured such that a width of the buffer channel pattern BCH changes from the first width W1 to the second width W2 when moving from the first subset of the channel patterns (e.g., that are included in the first region RG1) to the second subset of the channel patterns (e.g., that are included in the second region RG2). The first width W1 may be larger or smaller than the second width W2.

The buffer channel pattern BCH may include a first side surface SW1 extending in the second direction D2. The buffer channel pattern BCH may include a second side surface SW2 extending in the second direction D2. The connection side surface CSW may connect the first side surface SW1 to the second side surface SW2. The first side surface SW1 and the connection side surface CSW may be perpendicular to each other, when viewed in a plan view. The second side surface SW2 and the connection side surface CSW may be perpendicular to each other, when viewed in a plan view. For example, the first side surface SW1 may be adjacent to the first subset of the channel patterns (e.g., that are included in the first region RG1). For example, the second side surface SW2 may be adjacent to the second subset of the channel patterns (e.g., that are included in the second region RG2).

More specifically, the first side surface SW1 and the connection side surface CSW may be provided to form a first angle θ1. The second side surface SW2 and the connection side surface CSW may be provided to form a second angle θ2. Each of the first and second angles θ1 and θ2 may be in a range from 70° to 90°.

Referring to FIG. 4, the source/drain patterns may include a first-region source/drain pattern SDP1 and a second-region source/drain pattern SDP2, which are respectively provided on the first and second regions RG1 and RG2. For example, the first-region source/drain pattern SDP1 may be electrically connected to one of the first subset of the channel patterns. For example, the second-region source/drain pattern SDP2 may be electrically connected to one of the second subset of the channel patterns. The largest width SDW1 of the first-region source/drain pattern SDP1 in the first direction D1 may be larger than the largest width SDW2 of the second-region source/drain pattern SDP2 in the first direction D1. The largest width SDW1 of the first-region source/drain pattern SDP1 and the largest width SDW2 of the second-region source/drain pattern SDP2 may be proportional to the first width W1 and the second width W2, respectively.

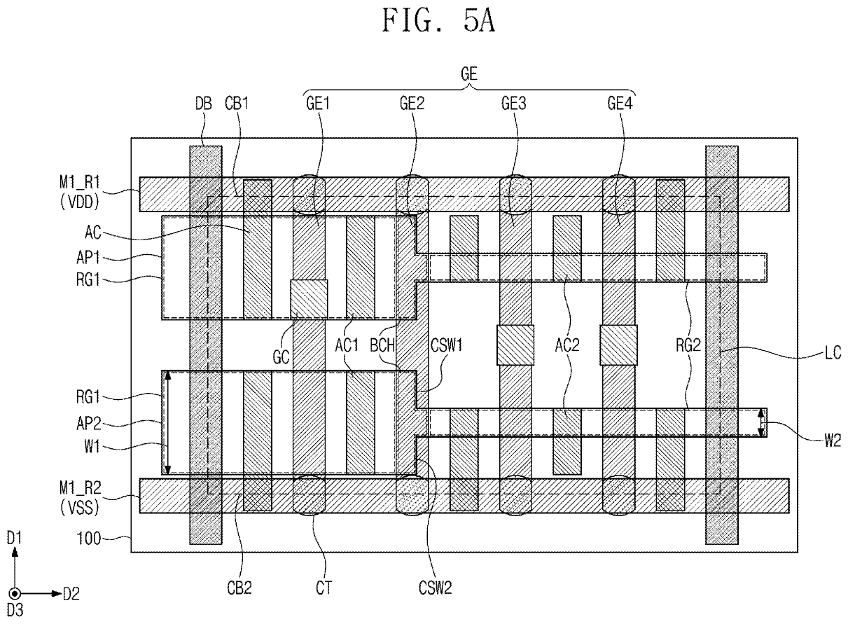

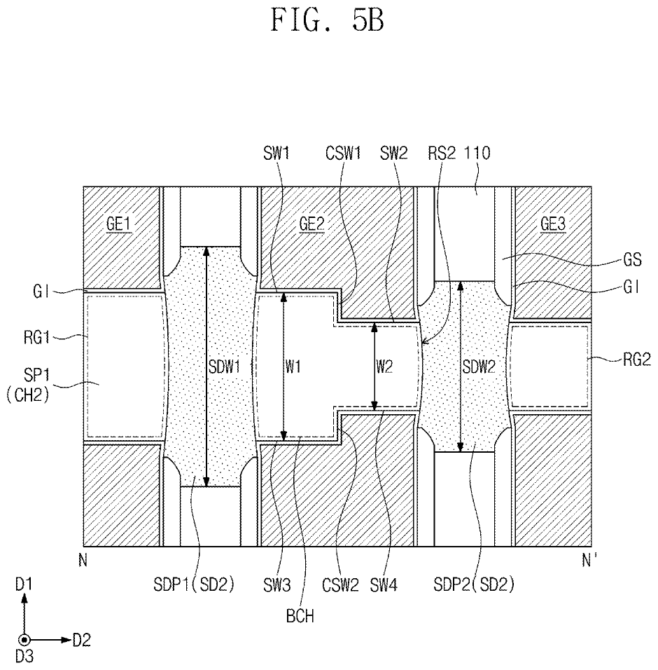

FIGS. 5A, 6A, and 7A are enlarged plan views illustrating the portion ‘M’ of FIG. 1. FIGS. 5B, 6B, and 7B are sectional views taken along the line N-N′ of FIG. 3B. For concise description, an element previously described with reference to FIGS. 2 to 4 may be identified by the same reference number without repeating an overlapping description thereof.

Referring to FIGS. 5A and 5B, the connection side surface CSW may include a first connection side surface CSW1 and a second connection side surface CSW2. At a boundary region having an abruptly-varying channel width (e.g., in the buffer channel pattern BCH), the first connection side surface CSW1 may be spaced apart from the second connection side surface CSW2 in the first direction D1. A length of the first connection side surface CSW1 may be different from a length of the second connection side surface CSW2. As an example, the length of the first connection side surface CSW1 may be longer or shorter than the length of the second connection side surface CSW2. As another example, the length of the first connection side surface CSW1 may be substantially equal to the length of the second connection side surface CSW2. For example, the length of the first connection side surface CSW1 and the length of the second connection side surface CSW2 may be taken along the first direction D1.

Referring to FIG. 5B, a third side surface SW3, which is opposite to the first side surface SW1, may be defined in the buffer channel pattern BCH. A fourth side surface SW4, which is opposite to the second side surface SW2, may be defined in the buffer channel pattern BCH. The first connection side surface CSW1 may connect the first side surface SW1 to the second side surface SW2. The second connection side surface CSW2 may connect the third side surface SW3 to the fourth side surface SW4.

Each of the first and second side surfaces SW1 and SW2 may be perpendicular to the first connection side surface CSW1, when viewed in a plan view. Each of the third and fourth side surfaces SW3 and SW4 may be perpendicular to the second connection side surface CSW2, when viewed in a plan view.

Referring to FIGS. 5A and 5B, the source/drain patterns may include a first-region source/drain pattern SDP1 and a second-region source/drain pattern SDP2, which are respectively provided on the first and second regions RG1 and RG2. For example, the first-region source/drain pattern SDP1 may be electrically connected to one of the first subset of the channel patterns. For example, the second-region source/drain pattern SDP2 may be electrically connected to one of the second subset of the channel patterns. The largest width SDW1 of the first-region source/drain pattern SDP1 in the first direction D1 may be larger than the largest width SDW2 of the second-region source/drain pattern SDP2 in the first direction D1. The largest width SDW1 of the first-region source/drain pattern SDP1 and the largest width SDW2 of the second-region source/drain pattern SDP2 may be proportional to the first width W1 and the second width W2, respectively.

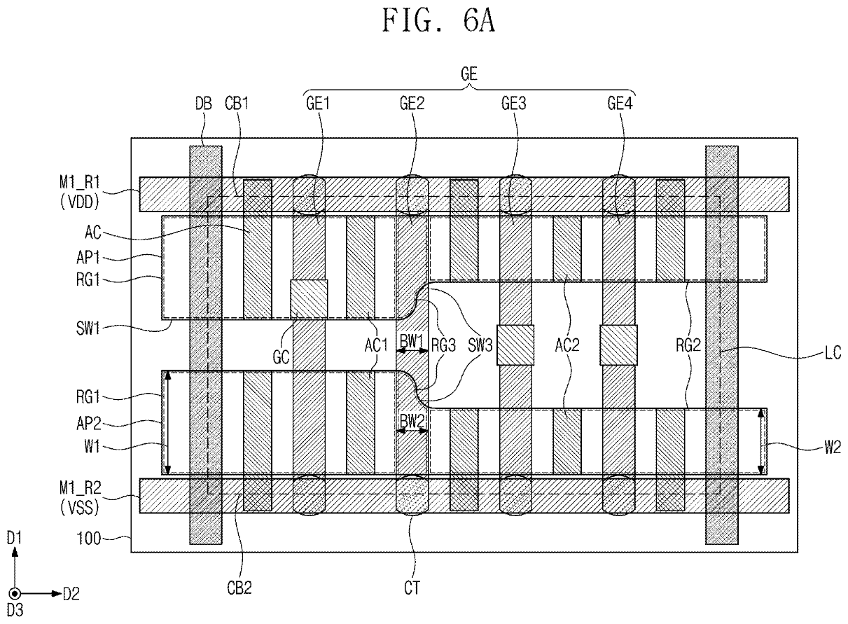

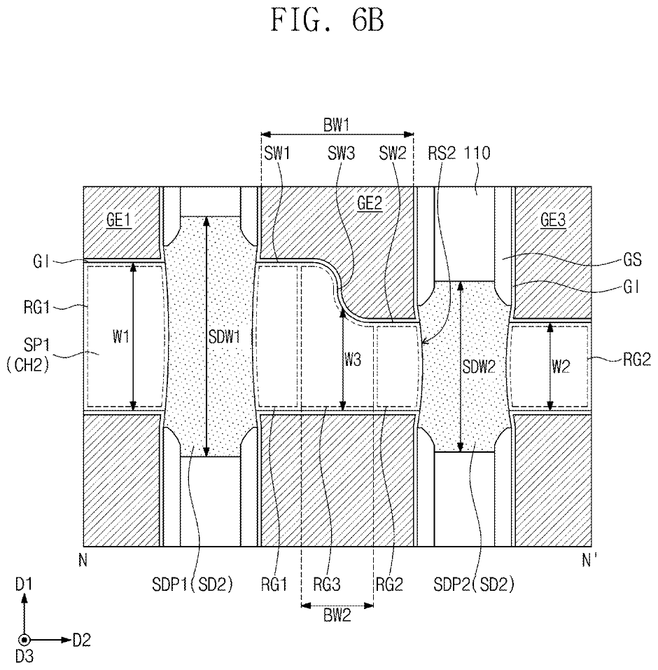

Referring to FIGS. 6A and 6B, the gate electrode GE may have a first horizontal width BW1 in the second direction D2. The channel pattern may include the first region RG1, which has the first width W1 in the first direction D1, and the second region RG2, which has the second width W2 in the first direction D1. The channel pattern may include a third region RG3, which is placed between the first region RG1 and the second region RG2 and has a varying channel width. The third region RG3 may be a buffer region whose width is changed from the first width W1 of the first region RG1 to the second width W2 of the second region RG2. The third region RG3 may have a second horizontal width BW2 in the second direction D2. The second horizontal width BW2 may be equal to or smaller than the first horizontal width BW1.

The third region RG3 may have a third width W3 in the first direction D1. The first width W1 may be larger than the second width W2. The third width W3 may be gradually decreased from the first region RG1 toward the second region RG2. For example, the third width W3 may gradually decrease as a distance from the first region RG1 increases in a direction toward the second region RG2 (e.g., the second direction D2). However, the present disclosure is not limited thereto. In some other embodiments, the first width W1 may be smaller than the second width W2. In some other embodiments, the third width W3 may be gradually increased from the first region RG1 toward the second region RG2. For example, the third width W3 may gradually increase as a distance from the first region RG1 increases in a direction toward the second region RG2 (e.g., the second direction D2).

Referring to FIG. 6B, the first region RG1 may include the first side surface SW1 extending in the second direction D2. The second region RG2 may include the second side surface SW2 extending in the second direction D2. The third region RG3 may include the third side surface SW3 connecting the first side surface SW1 to the second side surface SW2. In some embodiments, the third side surface SW3 may be provided to have a wavy or non-linear profile, when viewed in a plan view. In some other embodiments, the third side surface SW3 may have a line-shaped or linear profile extending in a direction inclined to the first and second side surfaces SW1 and SW2.

Referring to FIG. 6B, the source/drain patterns may include the first-region source/drain pattern SDP1 and the second-region source/drain pattern SDP2, which are provided on the first and second regions RG1 and RG2, respectively. The largest width SDW1 of the first-region source/drain pattern SDP1 in the first direction D1 may be larger than the largest width SDW2 of the second-region source/drain pattern SDP2 in the first direction D1. The largest width SDW1 of the first-region source/drain pattern SDP1 and the largest width SDW2 of the second-region source/drain pattern SDP2 may be proportional to the first width W1 and the second width W2, respectively.

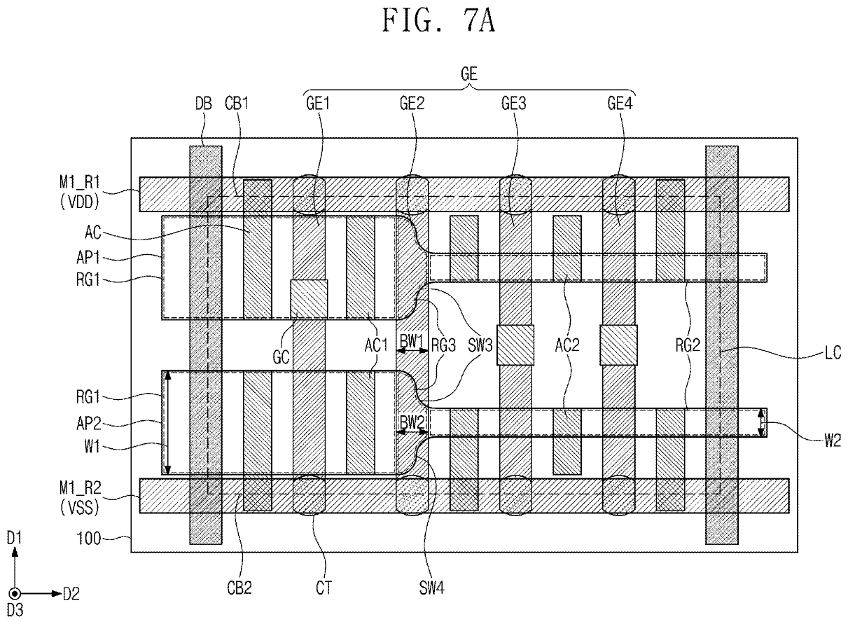

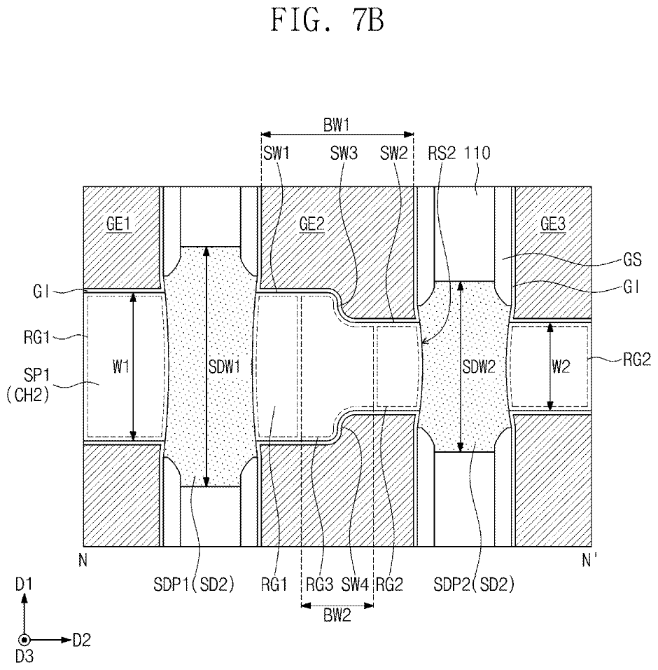

Referring to FIGS. 7A and 7B, the third region RG3 may further include the fourth side surface SW4 having a wavy or non-linear profile. The fourth side surface SW4 may be spaced apart from the third side surface SW3 with the third region RG3 interposed therebetween. For example, the fourth side surface SW4 may be spaced apart from the third side surface SW3 in the first direction D1. When viewed in a plan view, the third and fourth side surfaces SW3 and SW4 may be provided such that the third region RG3 has a symmetric shape with respect to an imaginary line parallel to the second direction D2 (e.g., see FIG. 7B). A width of the third side surface SW3 in the first direction D1 may be different from a width of the fourth side surface SW4 in the first direction D1.

Referring to FIGS. 4 to 7B, the width of the channel pattern may be abruptly or discontinuously changed. For example, the channel pattern may include a region whose width is abruptly changed. Furthermore, by adjusting the size of the source/drain pattern, it may be possible to prevent a leakage current from occurring.

Similar to the second active region AP2, the first active region AP1 may also include the first to third regions RG1 to RG3 (i.e., RG1, RG2, and RG3). The first to third regions RG1-RG3 of the first active region AP1 may be configured to have substantially the same features as the first to third regions RG1-RG3 of the second active region AP2 described above.

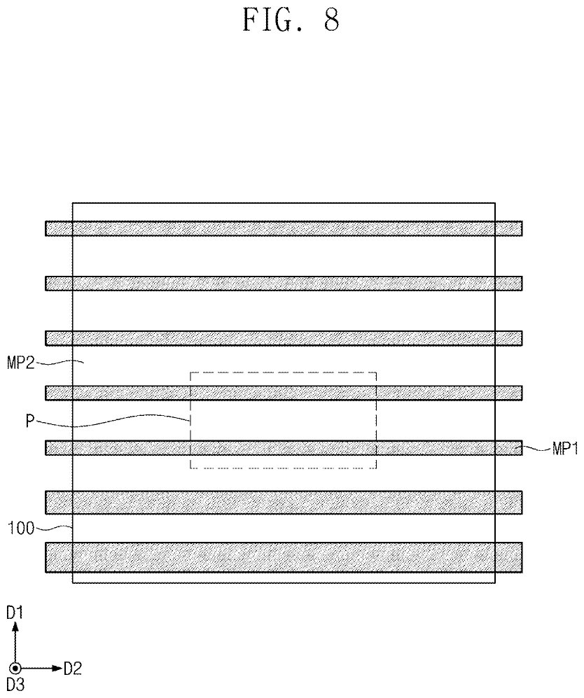

FIGS. 8 to 20E are diagrams illustrating a method of fabricating a semiconductor device, according to some embodiments of the inventive concept.

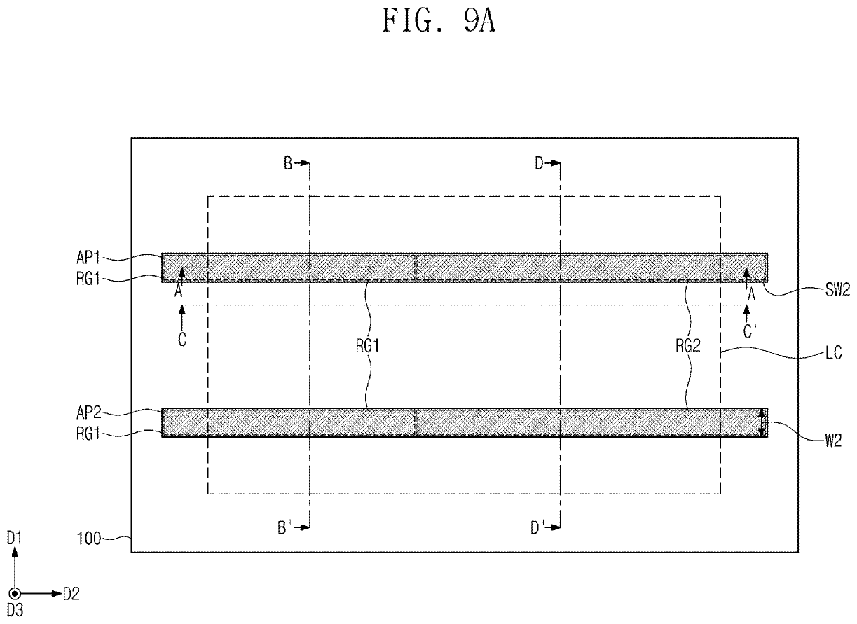

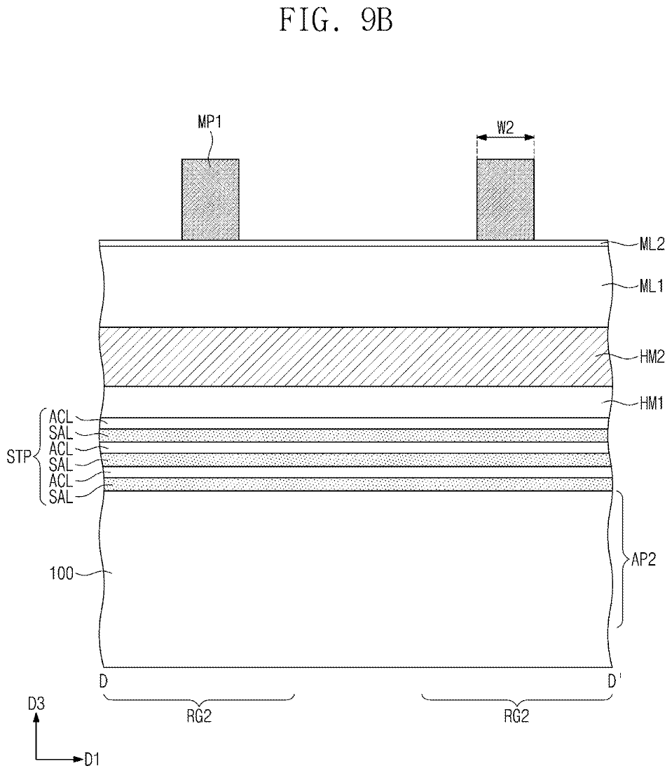

FIG. 9A is an enlarged plan view illustrating a portion ‘P’ of FIG. 8. FIG. 9B is a sectional view taken along a line D-D′ of FIG. 9A.

Referring to FIGS. 8, 9A, and 9B, the substrate 100 including the logic cell LC may be provided. Sacrificial layers SAL and active layers ACL may be alternately stacked on the substrate 100. The sacrificial and active layers SAL and ACL, which are stacked, may form a stacking pattern STP. Each of the sacrificial and active layers SAL and ACL may be formed of or include at least one of silicon (Si), germanium (Ge), or silicon germanium (SiGe), but the material of the active layers ACL may be different from that of the sacrificial layers SAL.

For example, the sacrificial layers SAL may be formed of or include silicon-germanium (SiGe), and the active layers ACL may be formed of or include silicon (Si). A germanium concentration of each of the sacrificial layers SAL may range from 10 at % to 30 at %.

Referring to FIGS. 9A and 9B, a first hard mask pattern HM1 may be coated on the stacking pattern STP, which is formed on the substrate 100. A second hard mask pattern HM2 may be coated on the first hard mask pattern HM1. A first mask layer ML1 may be coated on the second hard mask pattern HM2. A second mask layer ML2 may be coated on the first mask layer ML1.

Referring to FIGS. 8 to 9B, first patterns MP1 may be formed on the second mask layer ML2. The first patterns MP1 may have the second width W2 in the first direction D1. The first patterns MP1 may extend in the second direction D2 to be parallel to each other. The first patterns MP1 may be spaced apart from each other in the first direction D1 and may be parallel to each other.

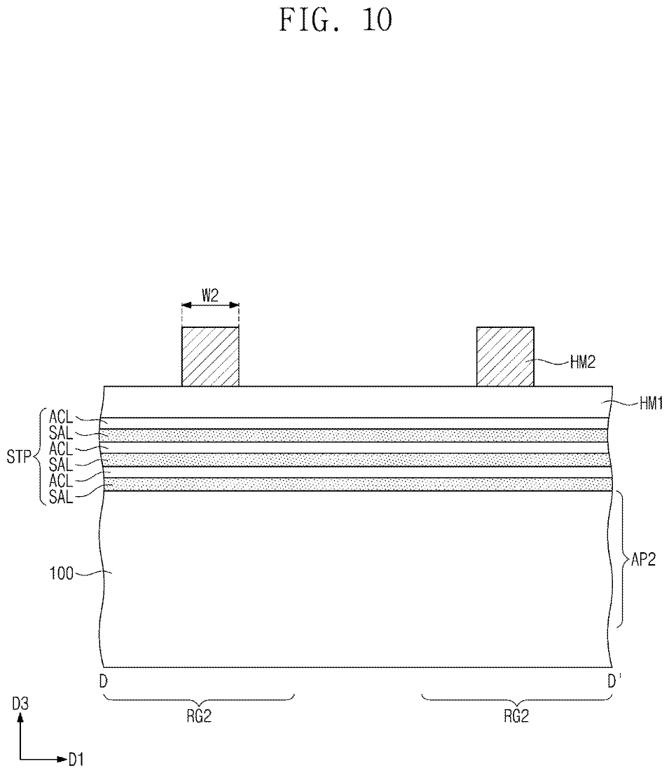

FIG. 10 is a sectional view taken along a line D-D′ of FIG. 9A. Referring to FIGS. 9B and 10, a selective etching process on the second mask layer ML2 may be performed to remove a portion of the second mask layer ML2 from a region that is not veiled by the first patterns MP1. A selective etching process on the first mask layer ML1 may be performed to remove a portion of the first mask layer ML1 from a region, which is not veiled or covered by a remaining portion of the second mask layer ML2.

Continuing to refer to FIGS. 9B and 10, a selective etching process on the second hard mask pattern HM2 may be performed to remove a portion of the second hard mask pattern HM2 from a region, which is not veiled or covered by a remaining portion of the first mask layer ML1. After the etching process, the second hard mask pattern HM2 may have the second width W2 in the first direction D1.

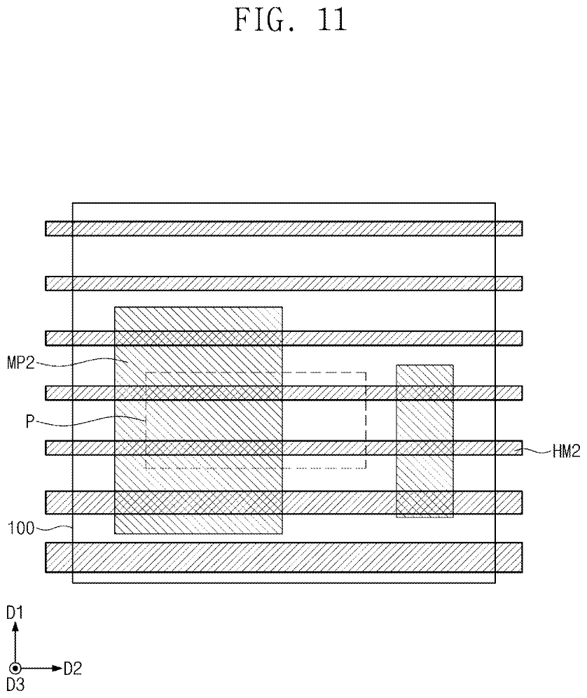

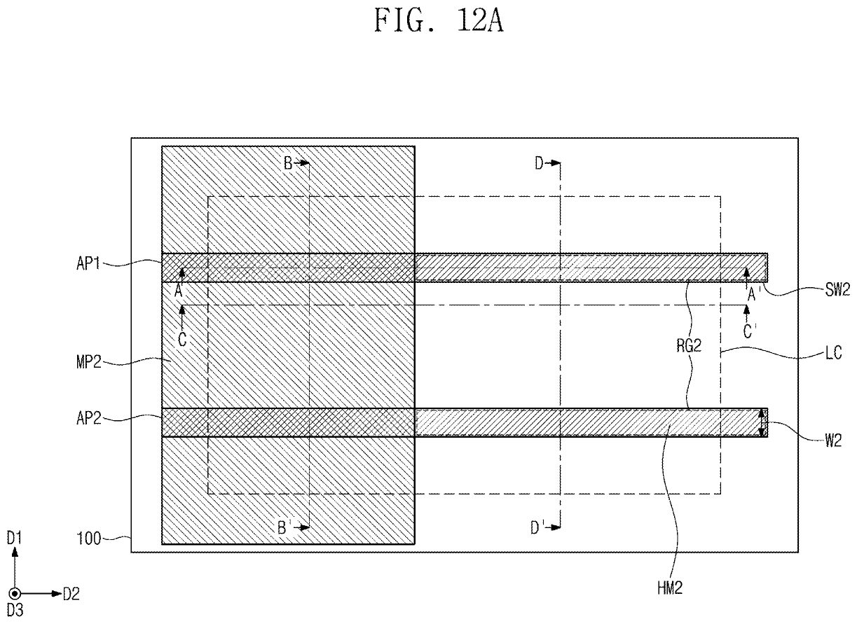

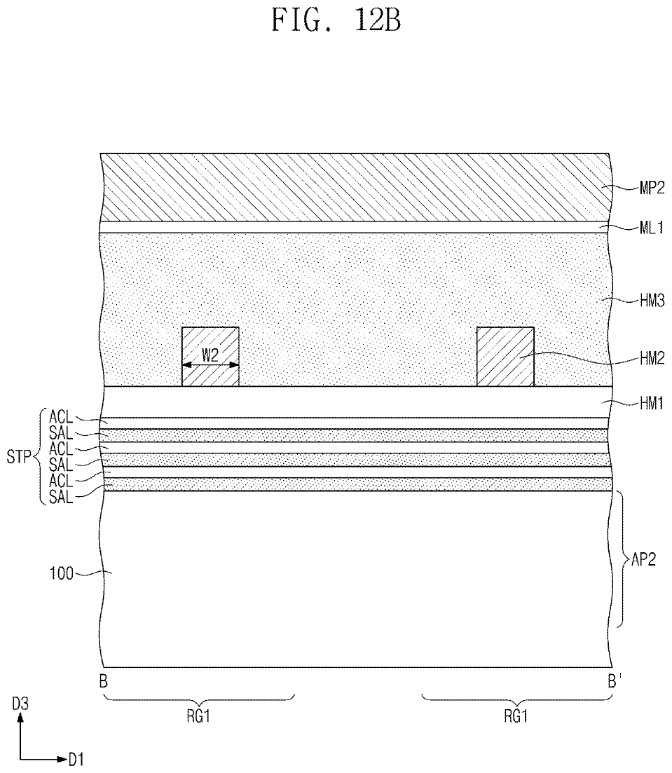

FIG. 12A is an enlarged plan view illustrating a portion ‘P’ of FIG. 11. FIG. 12B is a sectional view taken along a line B-B′ of FIG. 12A.

Referring to FIGS. 11 to 12B, a third hard mask pattern HM3 may be coated on the first hard mask pattern HM1 and the second hard mask pattern HM2. The first mask layer ML1 may be coated on the third hard mask pattern HM3. Second patterns MP2 may be formed on the first mask layer ML1. The second patterns MP2 may be formed on the substrate 100 to be parallel to the first direction D1(e.g., see FIG. 11). The second patterns MP2 may be formed to cover or be on a region, in which the channel pattern has the first width W1. The second patterns MP2 may not be formed on a region, in which the channel pattern has the second width W2.

A selective etching process on the first mask layer ML1 may be performed to remove a portion of the first mask layer ML1 from a region, which is not veiled or covered by the second patterns MP2. A selective etching process on the third hard mask pattern HM3 may be performed to remove a portion of the third hard mask pattern HM3 from a region, which is not veiled or covered by a remaining portion of the first mask layer ML1. Thereafter, the first mask layer ML1 may be removed.

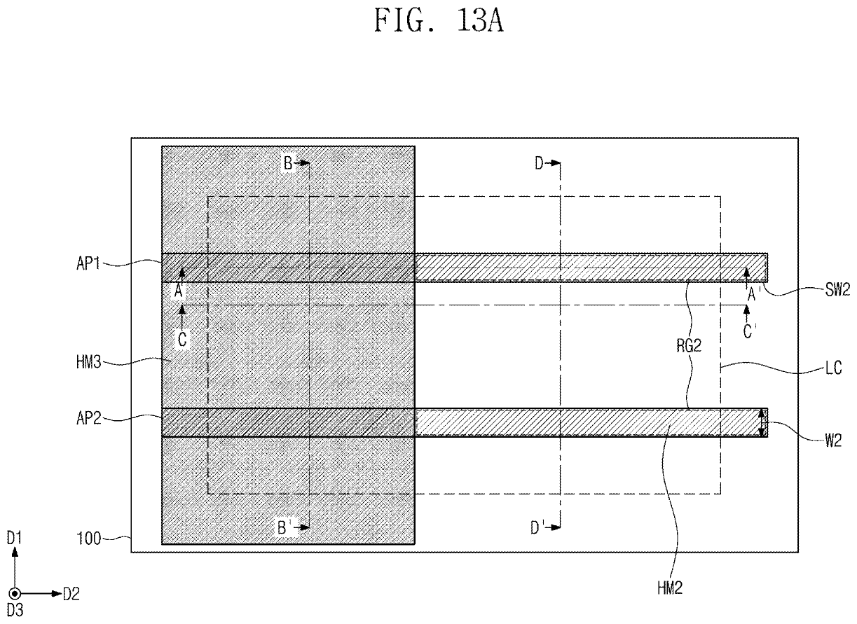

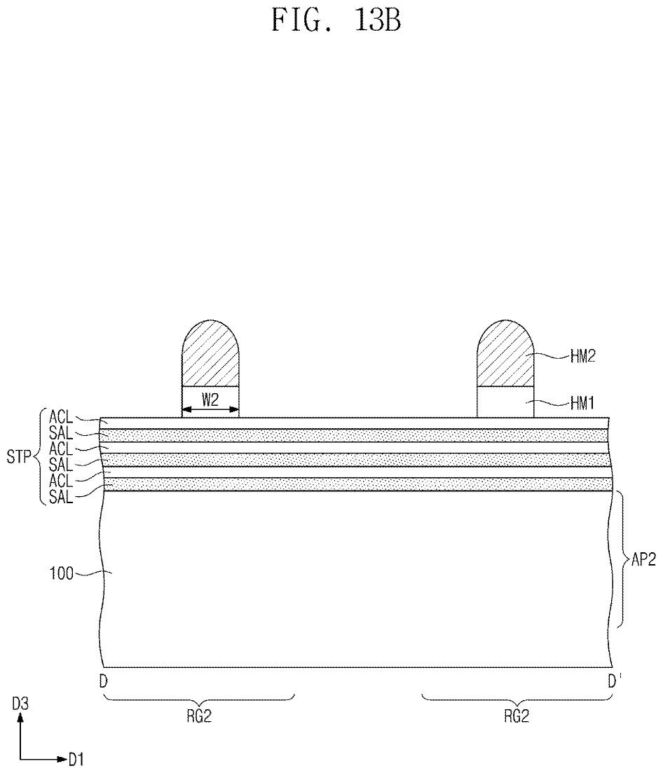

FIGS. 13B and 13C are sectional views, which are respectively taken along lines D-D′ and B-B′ of FIG. 13A.

Referring to FIGS. 13A and 13B, an exposed portion of the first hard mask pattern HM1 may be removed by the selective etching process on the first hard mask pattern HM1. Thus, the first hard mask pattern HM1 may have the second width W2 in a region that is not veiled or covered by the third hard mask pattern HM3. After the etching process, the second hard mask pattern HM2 and the third hard mask pattern HM3 may be removed.

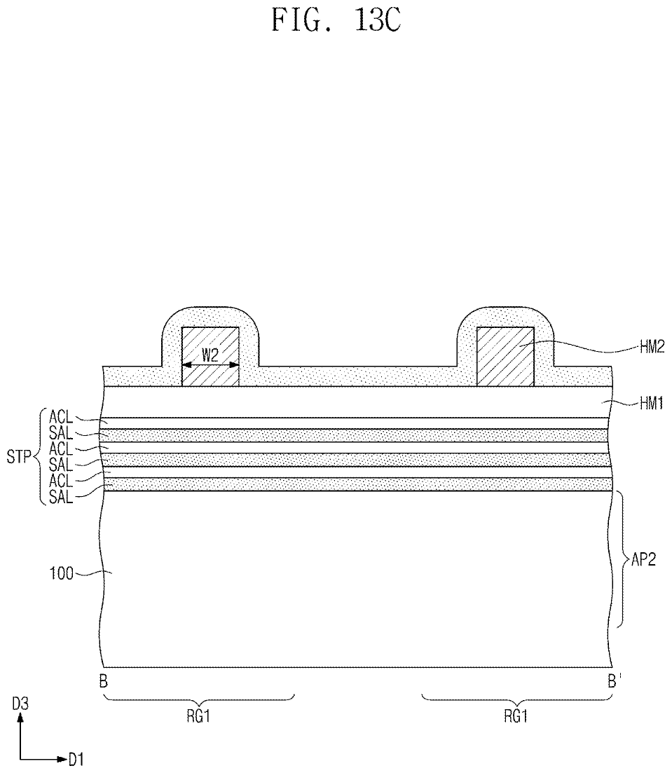

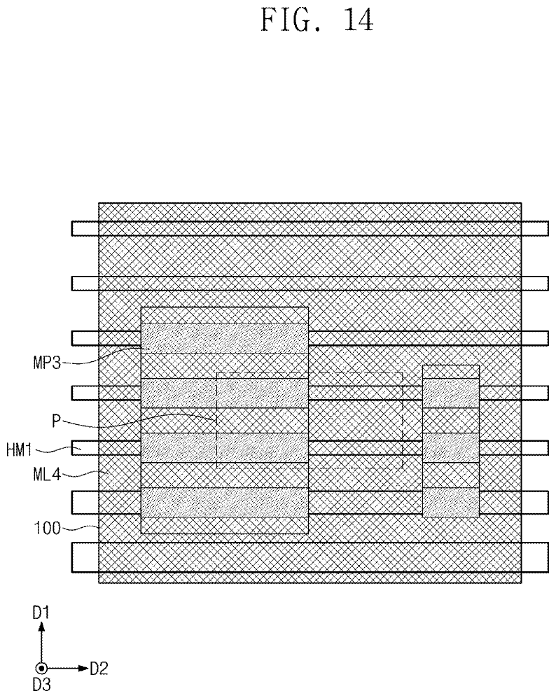

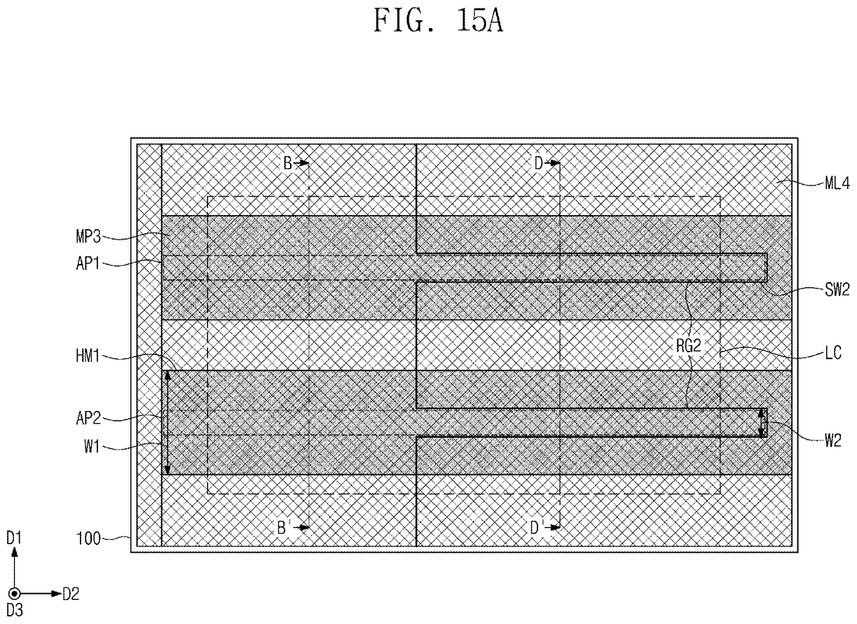

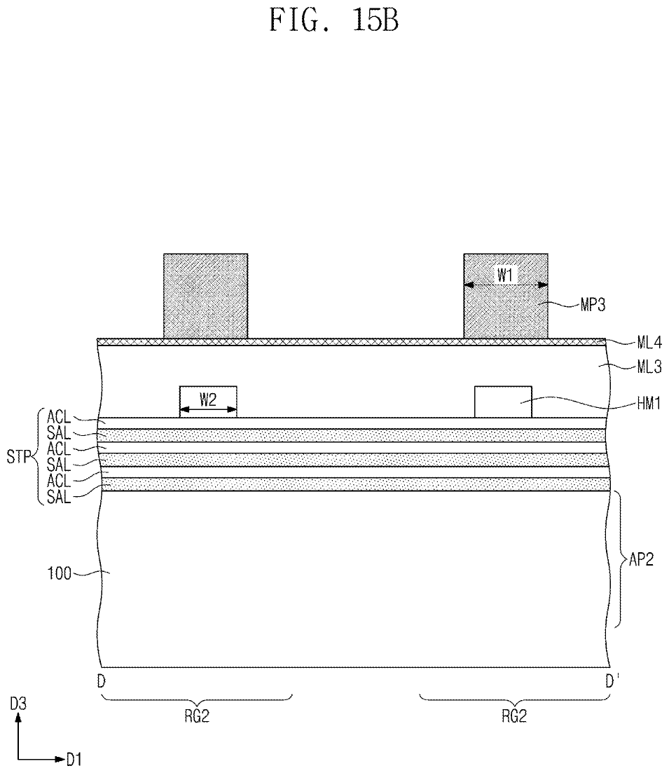

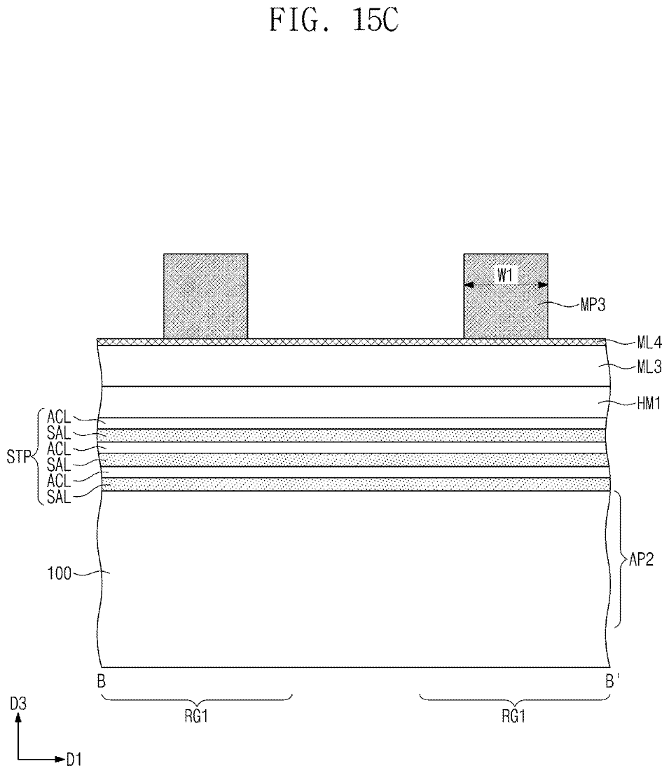

FIG. 15A is an enlarged plan view illustrating a portion ‘P’ of FIG. 14. FIGS. 15B and 15C are sectional views, which are respectively taken along lines D-D′ and B-B′ of FIG. 15A.

Referring to FIGS. 15A to 15C, a third mask layer ML3 may be coated on the first hard mask pattern HM1. A fourth mask layer ML4 may be coated on the third mask layer ML3. The third patterns MP3 may be formed on the fourth mask layer ML4. The third patterns MP3 may have the first width W1 in the first direction D1. The third patterns MP3 may be spaced apart from each other in the first direction D1 and may be disposed to be parallel to each other. The third patterns MP3 may be locally formed on channel patterns, which will be formed later.

A selective etching process may be performed to remove a portion of the fourth mask layer ML4 from a region, which is not veiled or covered by the third patterns MP3. A selective etching process may be performed to remove a portion of the third mask layer ML3 from a region, which is not veiled or covered by a remaining portion of the fourth mask layer ML4. Referring to FIG. 15B, a selective etching process on the first hard mask pattern HM1 may be performed to remove a portion of the first hard mask pattern HM1 from a region, which is not veiled or covered by a remaining portion of the third mask layer ML3.

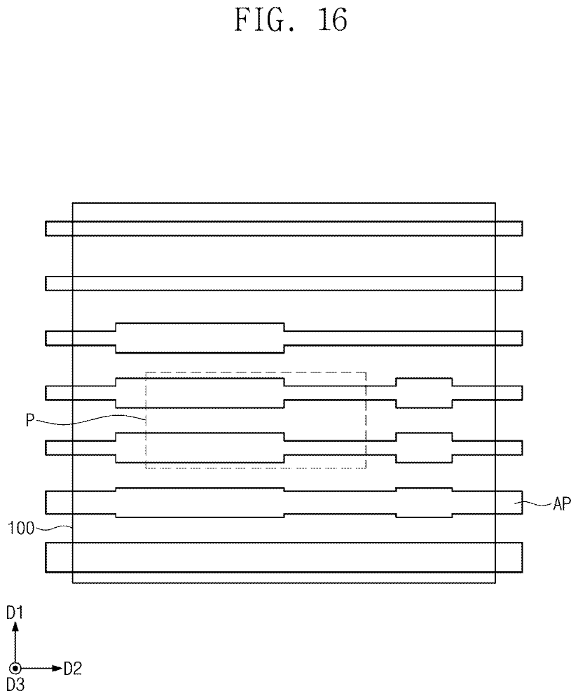

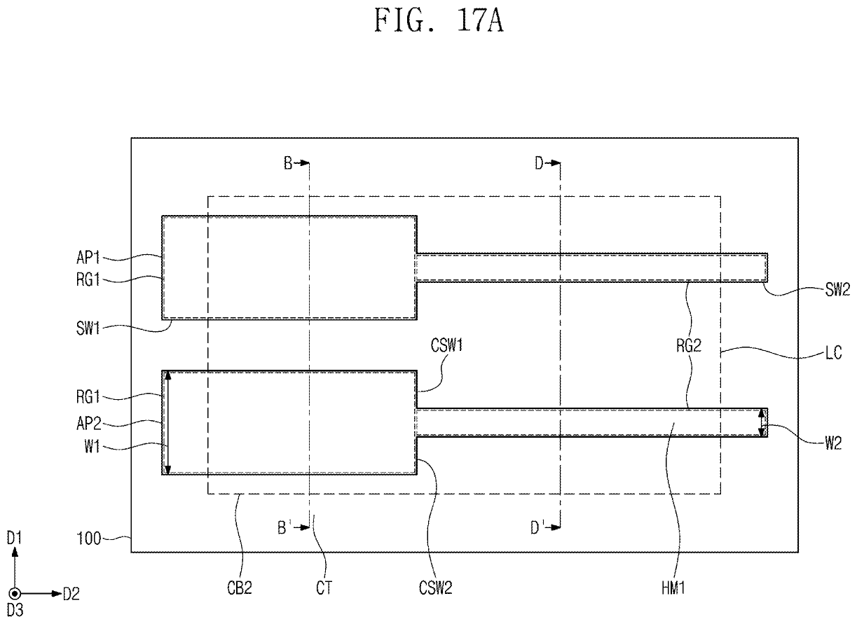

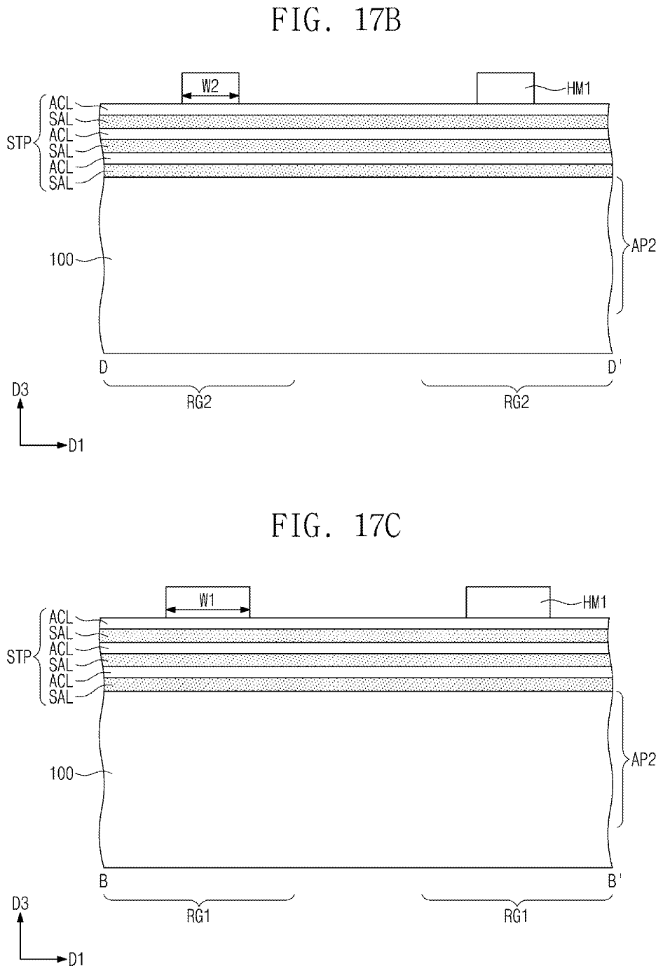

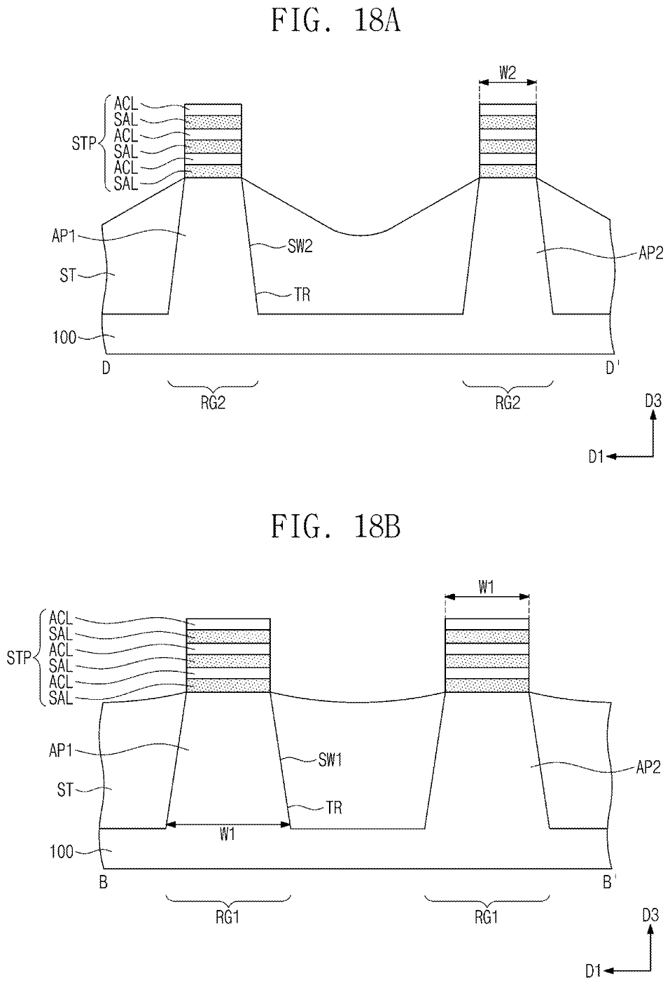

FIG. 17A is an enlarged plan view illustrating a portion ‘P’ of FIG. 16. FIGS. 17B and 17C are sectional views, which are respectively taken along lines D-D′ and B-B′ of FIG. 17A. FIGS. 18A and 18B are sectional views, which are respectively taken along lines D-D′ and B-B′ of FIG. 17A.

Referring to FIGS. 17A and 17B, after the etching process, the first hard mask pattern HM1 may include the second region RG2 having the second width W2. Referring to FIGS. 17A and 17C, after the etching process, the first hard mask pattern HM1 may include the first region RG1 having the first width W1.

Referring to FIGS. 18A and 18B, a patterning process using the first hard mask pattern HM1 as an etch mask may be performed to form the trench TR defining the first and second active regions AP1 and AP2. In some embodiments, the first and second active regions AP1 and AP2 may be PMOSFET and NMOSFET regions, respectively.

The stacking pattern STP may be formed on each of the first and second active regions AP1 and AP2. Each of the first and second active regions AP1 and AP2 may include the first region RG1 having the first width W1 and the second region RG2 having the second width W2.

When viewed in a plan view, each of the stacking patterns STP may have the same shape as a corresponding one of the first and second active regions AP1 and AP2. In other words, a width of the stacking pattern STP on the first region RG1 may be larger than a width of the stacking pattern STP on the second region RG2.

The device isolation layer ST may be formed to fill the trench TR. In detail, an insulating layer may be formed on the substrate 100 to cover or be on the first and second active regions AP1 and AP2 and the stacking patterns STP. The device isolation layer ST may be formed by recessing the insulating layer to expose the stacking patterns STP.

The device isolation layer ST may be formed of or include at least one of insulating materials (e.g., silicon oxide). The stacking patterns STP may be placed above the device isolation layer ST and may be exposed to the outside of the device isolation layer ST. In other words, the stacking patterns STP may protrude or extend vertically above the device isolation layer ST.

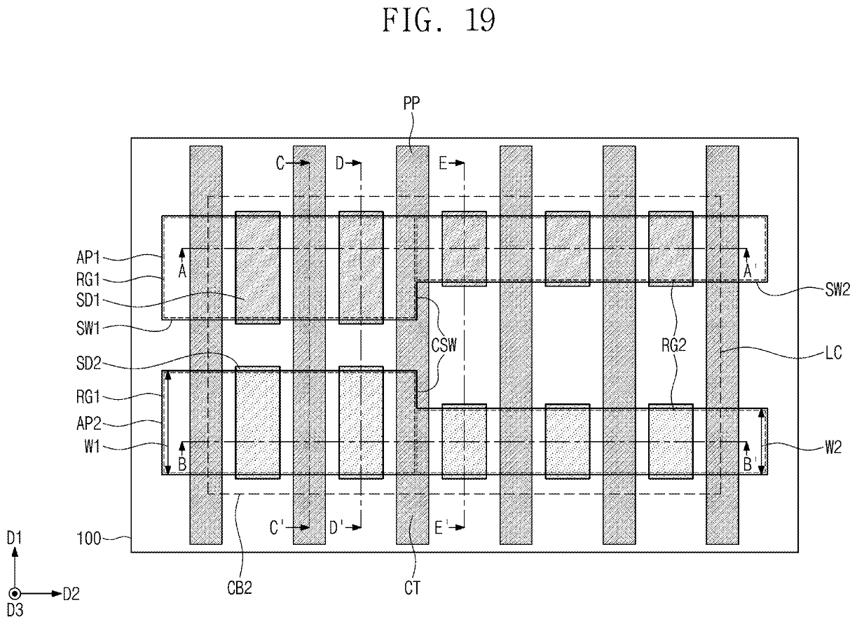

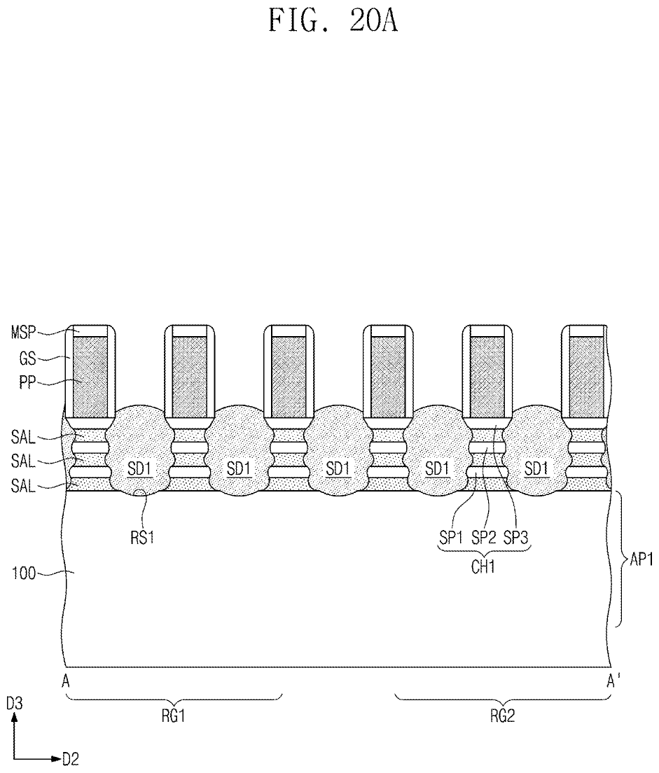

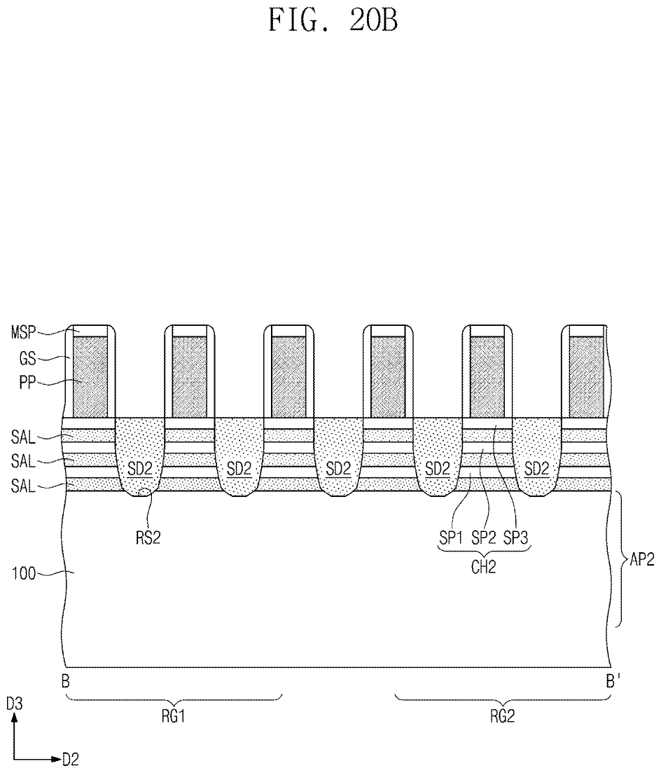

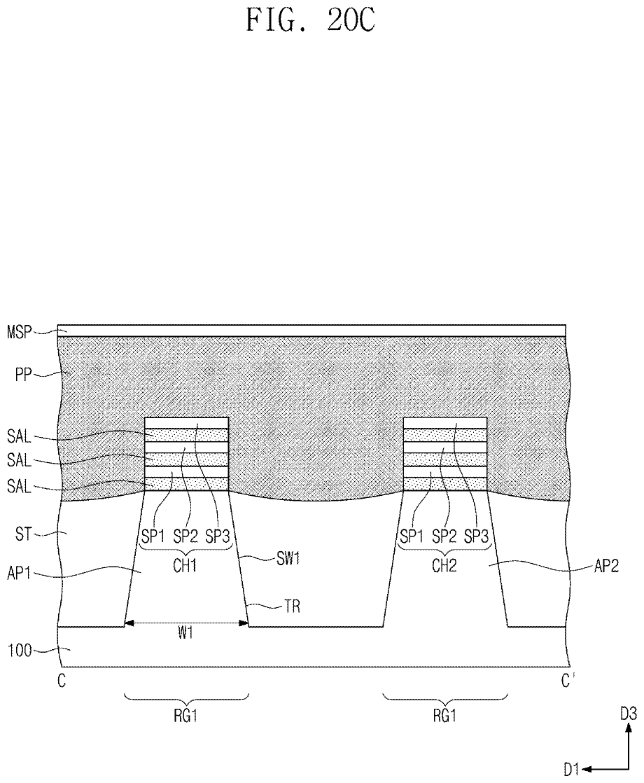

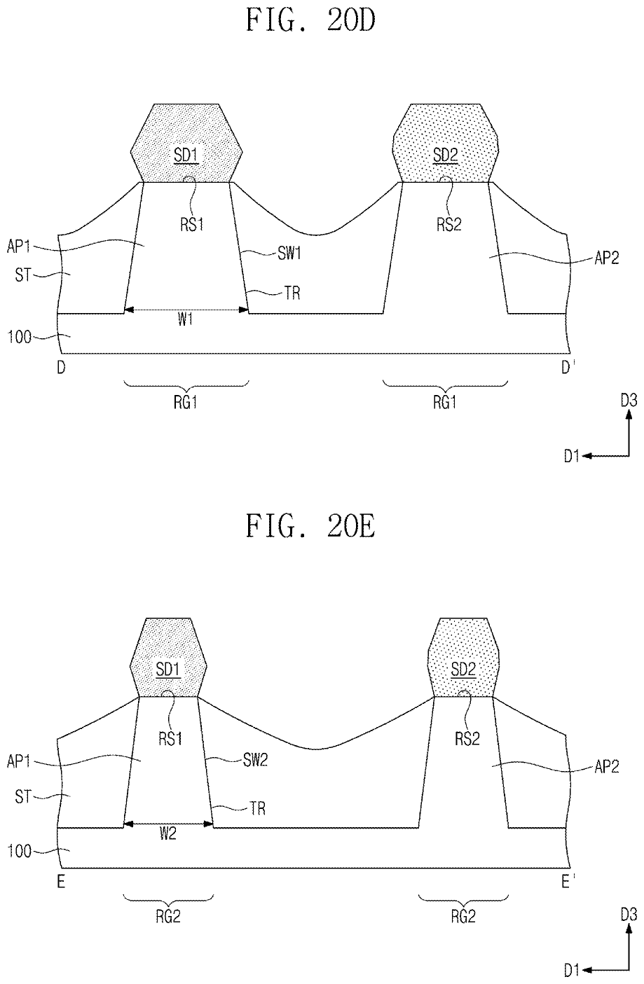

FIGS. 20A, 20B, 20C, 20D, and 20E are sectional views, which are respectively taken along lines A-A′, B-B′, C-C′, D-D′, and E-E′ of FIG. 19. Referring to FIGS. 19 and 20A to 20E, a plurality of sacrificial patterns PP may be formed on the substrate 100. The sacrificial patterns PP may be formed to cross the stacking patterns STP. Each of the sacrificial patterns PP may be a line- or bar-shaped pattern that extends in the first direction D1. The sacrificial patterns PP may be arranged, with a specific pitch, in the second direction D2. In some embodiments, the sacrificial patterns PP may be formed of or include polysilicon.

In detail, the formation of the sacrificial patterns PP may include forming a sacrificial semiconductor layer on the substrate 100, forming hard mask patterns MSP on the sacrificial semiconductor layer, and etching the sacrificial semiconductor layer using the hard mask patterns MSP as an etch mask.

A pair of the gate spacers GS may be formed on opposite side surfaces of each of the sacrificial patterns PP. The formation of the gate spacers GS may include conformally forming a gate spacer layer on the substrate 100 and anisotropically etching the gate spacer layer. The gate spacer layer may be formed of or include at least one of SiCN, SiCON, or SiN.

The first recesses RS1 may be formed in the stacking pattern STP on the first active region AP1. The second recesses RS2 may be formed in the stacking pattern STP on the second active region AP2. During the formation of the first and second recesses RS1 and RS2, the device isolation layer ST may also be recessed at both sides of each of the first and second active regions AP1 and AP2.

In detail, the first recesses RS1 may be formed by etching the stacking pattern STP on the first active region AP1 using the hard mask patterns MSP and the gate spacers GS as an etch mask. The first recess RS1 may be formed between a pair of the sacrificial patterns PP. The second recesses RS2 in the stacking pattern STP on the second active region AP2 may be formed by the same method as that for the first recesses RS1.

The first to third semiconductor patterns SP1, SP2, and SP3, which are sequentially stacked between adjacent ones of the first recesses RS1, may be formed from the active layers ACL. The first to third semiconductor patterns SP1, SP2, and SP3, which are sequentially stacked between adjacent ones of the second recesses RS2, may be formed from the active layers ACL. The first to third semiconductor patterns SP1, SP2, and SP3 between adjacent ones of the first recesses RS1 may constitute the first channel pattern CH1. The first to third semiconductor patterns SP1, SP2, and SP3 between the adjacent ones of the second recesses RS2 may constitute the second channel pattern CH2.

The first source/drain patterns SD1 may be formed in the first recesses RS1, respectively. In detail, the first source/drain pattern SD1 may be formed by a first selective epitaxial growth (SEG) process, in which an inner side surface of the first recess RS1 is used as a seed layer. The first SEG process may include a chemical vapor deposition (CVD) process or a molecular beam epitaxy (MBE) process.

The first source/drain pattern SD1 may be formed of or include a semiconductor material (e.g., SiGe) having a lattice constant greater than that of the substrate 100. During the first SEG process, impurities may be injected in an in-situ manner. Alternatively, impurities may be injected into the first source/drain pattern SD1, after the formation of the first source/drain pattern SD1. The first source/drain pattern SD1 may be doped to have a first conductivity type (e.g., a p-type).

The second source/drain patterns SD2 may be formed in the second recesses RS2, respectively. In detail, the second source/drain pattern SD2 may be formed by a second SEG process, in which an inner surface of the second recess RS2 is used as a seed layer. In some embodiments, the second source/drain pattern SD2 may be formed of or include the same semiconductor material (e.g., Si) as the substrate 100. The second source/drain pattern SD2 may be doped to have a second conductivity type (e.g., n-type). Inner spacers ISP may be respectively formed between the second source/drain pattern SD2 and the sacrificial layers SAL (e.g., see FIG. 3B, in which the sacrificial layers SAL have been removed).

Each of the first and second source/drain patterns SD1 and SD2 may be formed to have a size that is proportional to a width of a corresponding channel pattern.

The first interlayer insulating layer 110 may be formed to cover or be on the first and second source/drain patterns SD1 and SD2, the hard mask patterns MSP, and the gate spacers GS (e.g., see FIGS. 3A to 3E, in which the hard mask patterns MSP have been removed). In some embodiments, the first interlayer insulating layer 110 may include a silicon oxide layer. The first interlayer insulating layer 110 may be planarized to expose the top surfaces of the sacrificial patterns PP. The planarization of the first interlayer insulating layer 110 may be performed using an etch-back or chemical-mechanical polishing (CMP) process. The hard mask patterns MSP may be fully removed during the planarization process.

The sacrificial patterns PP may be replaced with gate electrodes GE. In detail, the exposed sacrificial pattern PP may be selectively removed. As a result of the removal of the sacrificial pattern PP, the sacrificial layers SAL may be exposed. The exposed sacrificial layers SAL may be selectively removed. The gate insulating layer GI and the gate electrode GE may be sequentially formed in an empty space, which is formed by removing the sacrificial pattern PP and the sacrificial layers SAL (e.g., see FIGS. 3A to 3C). The gate insulating layer GI may enclose or at least partially surround the first to third semiconductor patterns SP1, SP2, and SP3 (e.g., see FIGS. 3A to 3C). The gate capping pattern GP may be formed on the gate electrode GE (e.g., see FIGS. 3A to 3C).

The second interlayer insulating layer 120 may be formed on the first interlayer insulating layer 110 (e.g., see FIGS. 3A to 3E). The second interlayer insulating layer 120 may include a silicon oxide layer. The active contacts AC may be formed to penetrate or extend into the second and first interlayer insulating layers 120 and 110 and to be electrically connected to the first and second source/drain patterns SD1 and SD2 (e.g., see FIGS. 3A, 3B, 3D, and 3E). The gate contact GC may be formed to penetrate or extend into the second interlayer insulating layer 120 and the gate capping pattern GP and to be electrically connected to the gate electrode GE (e.g., see FIG. 3C).

The formation of the active and gate contacts AC and GC may include forming the barrier pattern BM and forming the conductive pattern FM on the barrier pattern BM (e.g., see FIGS. 3A to 3E). The barrier pattern BM may be conformally formed and may include a metal layer and/or a metal nitride layer. The conductive pattern FM may be formed of or include a low resistance metal.

A pair of the division structures DB may be formed at both sides of the logic cell LC (e.g., see FIGS. 2, 3A, and 3B). The division structure DB may be provided to penetrate or extend into the second interlayer insulating layer 120 and the gate electrode GE and may extend into the active region AP1 or AP2 (e.g., see FIGS. 3A and 3B). The division structure DB may be formed of or include an insulating material (e.g., silicon oxide or silicon nitride).

The third interlayer insulating layer 130 may be formed on the active contacts AC and the gate contacts GC (e.g., see FIGS. 3A to 3E). The first metal layer M1 may be formed in the third interlayer insulating layer 130 (e.g., see FIGS. 3A to 3E). The fourth interlayer insulating layer 140 may be formed on the third interlayer insulating layer 130 (e.g., see FIGS. 3A to 3E). The second metal layer M2 may be formed in the fourth interlayer insulating layer 140 (e.g., see FIGS. 3A to 3E).

In a semiconductor device according to some embodiments of the inventive concept, a channel pattern may include a buffer channel, at which a width of the channel pattern is abruptly changed. In some embodiments, a region, in which the width of the channel pattern is changed, may have a horizontal width that is smaller than a gate electrode. Thus, it may be possible to prevent a model-hardware correlation (MEW) from being deteriorated by the varying width of the channel pattern, and this may make it possible to prevent malfunction of the device and thereby to improve the reliability characteristics of the semiconductor device. Furthermore, it may be possible to prevent an increase of a leakage current, which may be caused by the change in the width of the channel pattern, and thereby to improve the electric characteristics of the semiconductor device.

As used herein, the terms “comprises”, “comprising”, “includes”, “including”, “has”, “having” and any other variations thereof specify the presence of the stated features, integers, steps, operations, elements, and/or components, but do not preclude the presence or addition of one or more other features, integers, steps, operations, elements, components, and/or groups thereof.

While example embodiments of the inventive concept have been particularly shown and described, it will be understood by one of ordinary skill in the art that variations in form and detail may be made therein without departing from the scope of the attached claims.

What is claimed is:

1. A semiconductor device, comprising:
an active region on a substrate;
source/drain patterns on the active region;
channel patterns on the active region and electrically connected to respective pairs of the source/drain patterns, each of the channel patterns comprising a plurality of semiconductor patterns that are vertically stacked and spaced apart from each other;
gate electrodes that are on the channel patterns, respectively, and extend in a first direction parallel to each other; and
active contacts electrically connected to the source/drain patterns, respectively,
wherein the channel patterns comprise a first subset of the channel patterns, each of which has a first width in the first direction, and a second subset of the channel patterns, each of which has a second width in the first direction,
wherein the first subset and the second subset of the channel patterns are adjacent to each other in a second direction that intersects the first direction,
wherein the channel patterns further comprise a buffer channel pattern between the first subset and the second subset of the channel patterns,
wherein the buffer channel pattern comprises a connection side surface that extends in the first direction, and
wherein the connection side surface is configured such that a width of the buffer channel pattern changes from the first width to the second width when moving from the first subset to the second subset of the channel patterns.

2. The semiconductor device of claim 1, wherein the first width is larger than the second width.

3. The semiconductor device of claim 1, wherein the first width is smaller than the second width.

4. The semiconductor device of claim 1, wherein the buffer channel pattern comprises a first side surface that is adjacent to the first subset of the channel patterns and extends in the second direction, and a second side surface that is adjacent to the second subset of the channel patterns and extends in the second direction, and
wherein the connection side surface connects the first side surface to the second side surface.

5. The semiconductor device of claim 4, wherein the first side surface and the connection side surface form a first angle,
wherein the second side surface and the connection side surface form a second angle, and
wherein each of the first and second angles is in a range from 70° to 90°.

6. The semiconductor device of claim 1, wherein the connection side surface comprises a first connection side surface and a second connection side surface, and
wherein the first connection side surface is spaced apart from the second connection side surface in the first direction.

7. The semiconductor device of claim 6, wherein a length of the first connection side surface in the first direction is different from a length of the second connection side surface in the first direction.

8. The semiconductor device of claim 1, wherein the source/drain patterns comprise a first-region source/drain pattern electrically connected to one of the first subset of the channel patterns and a second-region source/drain pattern electrically connected to one of the second subset of the channel patterns, and
wherein a largest width of the first-region source/drain pattern in the first direction is larger than a largest width of the second-region source/drain pattern in the first direction.

9. A semiconductor device, comprising:
an active region on a substrate;
a source/drain pattern on the active region;
a channel pattern on the active region and electrically connected to the source/drain pattern, the channel pattern comprising a plurality of semiconductor patterns that are vertically stacked and spaced apart from each other;
a gate electrode that is on the channel pattern and extends in a first direction, the gate electrode having a first horizontal width in a second direction that intersects the first direction; and
an active contact electrically connected to the source/drain pattern,
wherein the channel pattern comprises:
a first region that has a first width in the first direction;
a second region that has a second width in the first direction; and
a third region between the first region and the second region, the third region having a varying channel width,
wherein the third region has a third width in the first direction,
wherein the third region has a second horizontal width in the second direction, and
wherein the second horizontal width is smaller than the first horizontal width.

10. The semiconductor device of claim 9, wherein the first width is larger than the second width, and
wherein the third width of the third region gradually decreases as a distance from the first region increases in a direction toward the second region.

11. The semiconductor device of claim 9, wherein the first width is smaller than the second width, and
wherein the third width of the third region gradually increases as a distance from the first region increases in a direction toward the second region.

12. The semiconductor device of claim 9, wherein the first region comprises a first side surface that extends in the second direction,
wherein the second region comprises a second side surface that extends in the second direction,
wherein the third region comprises a third side surface that connects the first side surface to the second side surface, and
wherein the third side surface has a non-linear profile, when viewed in a plan view.

13. The semiconductor device of claim 12, wherein the third region further comprises a fourth side surface that has a non-linear profile, and
wherein the third and fourth side surfaces of the third region are opposite to each other.

14. The semiconductor device of claim 13, wherein a width of the fourth side surface in the first direction is different from a width of the third side surface in the first direction.

15. The semiconductor device of claim 9, wherein the source/drain pattern comprises a first-region source/drain pattern and a second-region source/drain pattern on the first and second regions, respectively, and
wherein a largest width of the first-region source/drain pattern in the first direction is larger than a largest width of the second-region source/drain pattern in the first direction.

16. A semiconductor device, comprising:
a substrate that includes an active region;
a device isolation layer that defines the active region;
source/drain patterns on the active region;
channel patterns on the active region and electrically connected to respective pairs of the source/drain patterns, each of the channel patterns comprising a plurality of semiconductor patterns that are vertically stacked and spaced apart from each other;
gate electrodes that are on the channel patterns, respectively, and extend in a first direction parallel to each other;
gate insulating layers, each of the gate insulating layers between a respective one of the gate electrodes and a respective one of the channel patterns;
gate spacers, each of the gate spacers on a side surface of a respective one of the gate electrodes;
gate capping patterns, each of the gate capping patterns on a top surface of a respective one of the gate electrodes;
an interlayer insulating layer on the gate capping pattern;
active contacts that extend into the interlayer insulating layer and are electrically connected to the source/drain patterns, respectively;
metal-semiconductor compound layers, each of the metal-semiconductor compound layers between a respective one of the active contacts and a respective one of the source/drain patterns;
gate contacts that extend into the interlayer insulating layer and the gate capping pattern and are electrically connected to the gate electrodes, respectively;
a first metal layer on the interlayer insulating layer, the first metal layer comprising first interconnection lines that are electrically connected to at least one of the active contacts and the gate contacts; and
a second metal layer on the first metal layer, the second metal layer comprising second interconnection lines that are electrically connected to the first metal layer,
wherein the channel patterns comprise a first subset of the channel patterns, each of which has a first width in the first direction, and a second subset of the channel patterns, each of which has a second width in the first direction,
wherein the channel patterns further comprise a buffer channel pattern between the first subset and the second subset of the channel patterns, and
wherein the buffer channel pattern is configured such that a width of the buffer channel pattern changes from the first width to the second width when moving from the first subset to the second subset of the channel patterns.

17. The semiconductor device of claim 16, wherein the source/drain patterns comprise a first-region source/drain pattern electrically connected to one of the first subset of the channel patterns and a second-region source/drain pattern electrically connected to one of the second subset of the channel patterns, and
wherein a largest width of the first-region source/drain pattern in the first direction is larger than a largest width of the second-region source/drain pattern in the first direction.

18. The semiconductor device of claim 16, wherein the first width is different from the second width.

19. The semiconductor device of claim 16, wherein the buffer channel pattern comprises a connection side surface that extends in the first direction.

20. The semiconductor device of claim 19, wherein the buffer channel pattern comprises a first side surface that is adjacent to the first subset of the channel patterns and extends in a second direction intersecting the first direction, and a second side surface that is adjacent to the second subset of the channel patterns and extends in the second direction, and
wherein the connection side surface connects the first side surface to the second side surface.
